(19) United States
(12) Patent Application Publication
(10) Pub. No.: US 2018/0309080 A1
(43) Pub. Date: Oct. 25, 2018

(54) Light-Emitting Element, Light-Emitting Device, Electronic Device, and Lighting Device

(71) Applicant: Semiconductor Energy Laboratory Co., Ltd., Kanagawa-ken (JP)

(72) Inventors: Hiromi SEO, Sagamihara (JP); Satoshi SEO, Sagamihara (JP)

(73) Assignee: Semiconductor Energy Laboratory Co., Ltd., Kanagawa-ken (JP)

(21) Appl. No.: 16/020,242

(22) Filed: Jun. 27, 2018

Related U.S. Application Data
(63) Continuation of application No. 13/958,127, filed on Aug. 2, 2013.

(30) Foreign Application Priority Data
Aug. 3, 2012 (JP) 2012-172824

(51) Int. Cl. H01L 51/50; H01L 51/52; H01L 51/00

(52) U.S. Cl. CPC H01L 51/5028; H01L 51/5296; H01L 2251/552; H01L 51/5004; H01L 51/0072

(57) ABSTRACT

The light-emitting element has a structure in which a first organic compound and a second organic compound form an exciplex (excited complex) in a light-emitting layer. The S1 level and the T1 level of the formed exciplex are positioned extremely close to each other compared to the S1 level and the T1 level of the respective substances (the first organic compound and the second organic compound) before the formation of the exciplex.

This application is a continuation of copending U.S. application Ser. No. 13/958,127, filed on Aug. 2, 2013 which is incorporated herein by reference.

### BACKGROUND OF THE INVENTION

### 1. Field of the Invention

One embodiment of the present invention relates to a light-emitting element in which an organic compound capable of emitting light by application of an electric field is provided between a pair of electrodes, and also relates to a light-emitting device, an electronic device, and a lighting device including such a light-emitting element.

### 2. Description of the Related Art

Light-emitting elements including an organic compound as a luminous body, which have features such as thinness, lightness, high-speed response, and DC driving at low voltage, are expected to be applied to next-generation flat panel displays. In particular, display devices in which light-emitting elements are arranged in a matrix are considered to have advantages of a wide viewing angle and high visibility over conventional liquid crystal display devices.

A light-emitting element is said to have the following light emission mechanism: when voltage is applied between a pair of electrodes with an EL layer including a light-emitting substance provided therebetween, electrons injected from the cathode and holes injected from the anode are recombined in a light emission center of the EL layer to form molecular excitons, and energy is released and light is emitted when the molecular excitons relax to the ground state. The excited states generated in the case of using an organic compound as a light-emitting substance are a singlet excited state and a triplet excited state. Luminescence from the singlet excited state (S1) is referred to as fluorescence, and luminescence from the triplet excited state (T1) is referred to as phosphorescence. The statistical generation ratio of the excited states in a light-emitting element is considered to be S1:T1=1:3.

To improve element characteristics of such a light-emitting element, development has been made; for example, an element structure that utilizes phosphorescence as well as fluorescence by adding a newly developed dopant has been developed (e.g., see Patent Document 1).

### REFERENCE

### Patent Document

[Patent Document 1] Japanese Published Patent Application No. 2010-182699

### SUMMARY OF THE INVENTION

One embodiment of the present invention does not employ the above-described method for increasing emission efficiency of a light-emitting element by utilizing phosphorescence that is made possible by adding a newly developed dopant, but provides a light-emitting element that can increase emission efficiency by having a generation probability of the singlet excited state (S1) in a light-emitting layer of the light-emitting element of more than or equal to the theoretical value (25%). Further, one embodiment of the present invention provides a light-emitting element with long lifetime.

One embodiment of the present invention has a structure in which a first organic compound and a second organic compound form an exciplex (excited complex) in a light-emitting layer of a light-emitting element. The S1 level and the T1 level of the formed exciplex are positioned extremely close to each other compared to the S1 level and the T1 level of the respective substances (the first organic compound and the second organic compound) before the formation of the exciplex. Since the excitation lifetime of T1 of the exciplex is long, part of energy in T1 of the exciplex easily transfers to S1 without thermal deactivation. That is, even when the theoretical generation probability of S1 right after recombination of carriers is 25%, the above-described process allows more S1 to be generated at the end. Thus, one embodiment of the present invention has a feature of increasing emission efficiency of a light-emitting element by utilizing luminescence from S1.

One embodiment of the present invention is a light-emitting element including, between a pair of electrodes, a layer including a first organic compound having an electron-transport property and a second organic compound having a p-phenylenediamine skeleton. The first organic compound having an electron-transport property and the second organic compound having a p-phenylenediamine skeleton are a combination that forms an exciplex.

Another embodiment of the present invention is a light-emitting element including, between a pair of electrodes, a layer including a first organic compound having an electron-transport property and a second organic compound having a 4-(9H-carbazol-9-yl)aniline skeleton. The first organic compound having an electron-transport property and the second organic compound having a 4-(9H-carbazol-9-yl)aniline skeleton are a combination that forms an exciplex.

Another embodiment of the present invention is a light-emitting element including, between a pair of electrodes, a layer including a first organic compound having an electron-transport property and a second organic compound having a 9-aryl-9H-carbazol-3-amine skeleton. The first organic compound having an electron-transport property and the second organic compound having a 9-aryl-9H-carbazol-3-amine skeleton are a combination that forms an exciplex.

Another embodiment of the present invention is a light-emitting element including, between a pair of electrodes, a layer including a first organic compound having an electron-transport property and a second organic compound having a skeleton represented by General Formula (G1). The first organic compound having an electron-transport property and the second organic compound having a skeleton represented by General Formula (G1) are a combination that forms an exciplex.

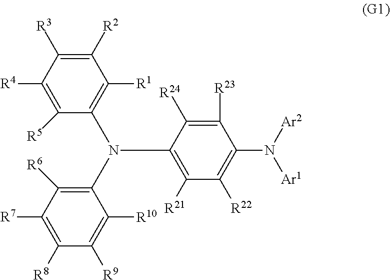

In the formula, R¹ to R¹⁰ independently represent hydrogen, an alkyl group having 1 to 4 carbon atoms, a phenyl group, or a biphenyl group; R²¹ to R²⁴ independently represent hydrogen or an alkyl group having 1 to 4 carbon atoms; Ar¹ and Ar² independently represent a phenyl group, a biphenyl group, a fluorenyl group, a spirofluorenyl group, or a carbazolyl group, which is substituted or unsubstituted; when Ar¹ and Ar² include a substituent, the substituent is independently an alkyl group having 1 to 4 carbon atoms, a phenyl group, a biphenyl group, a 9-arylcarbazolyl group having 18 to 30 carbon atoms, or a diarylamino group having 12 to 60 carbon atoms; R¹ and R²⁴, R⁵ and R⁶, R¹⁰ and R²¹, R²² and Ar¹, and Ar² and R²³ may form a single bond therebetween.

Another embodiment of the present invention is a light-emitting element including, between a pair of electrodes, a layer including a first organic compound having an electron-transport property and a second organic compound having a skeleton represented by General Formula (G2). The first organic compound having an electron-transport property and the second organic compound having a skeleton represented by General Formula (G2) are a combination that forms an exciplex.

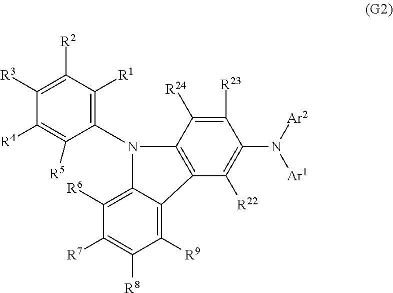

In the formula, R¹ to R⁹ independently represent hydrogen, an alkyl group having 1 to 4 carbon atoms, a phenyl group, or a biphenyl group; R²² to R²⁴ independently represent hydrogen or an alkyl group having 1 to 4 carbon atoms; Ar¹ and Ar² independently represent a phenyl group, a biphenyl group, a fluorenyl group, a spirofluorenyl group, or a carbazolyl group, which is substituted or unsubstituted; when Ar¹ and Ar² include a substituent, the substituent is independently an alkyl group having 1 to 4 carbon atoms, a phenyl group, a biphenyl group, a 9-arylcarbazolyl group having 18 to 30 carbon atoms, or a diarylamino group having 12 to 60 carbon atoms; R¹ and R²⁴, R⁵ and R⁶, R²² and Ar¹, and Ar² and R²³ may form a single bond therebetween.

In the above-described structures, the generation probability of the singlet excited state (S1) in the exciplex formed by the first organic compound having an electron-transport property and the second organic compound having any of the p-phenylenediamine skeleton, the 4-(9H-carbazol-9-yl)aniline skeleton, the 9-aryl-9H-carbazol-3-amine skeleton, the skeleton represented by General Formula (G1), or the skeleton represented by General Formula (G2) is higher than the theoretical value (25%).

Therefore, by forming an exciplex in a light-emitting layer between a pair of electrodes, a light-emitting element of one embodiment of the present invention can have high emission efficiency.

Further, as described above, the S1 level and the T1 level of the exciplex formed in the light-emitting layer are positioned extremely close to each other. In the case of employing a structure in which a light-emitting substance that converts triplet excited energy into light emission is newly added into the light-emitting layer, the overlap between the emission spectrum of the exciplex and the absorption spectrum of the light-emitting substance that converts triplet excited energy into light emission can be large, which can increase the efficiency of energy transfer from T1 of the exciplex to the light-emitting substance that converts triplet excited energy into light emission. Accordingly, a light-emitting element with high emission efficiency can be achieved.

In the above-described structures, an electron-transport material having an electron mobility of 10⁻⁶ cm²/Vs or higher, specifically, a π-electron deficient heteroaromatic compound is used mainly as the first organic compound having an electron-transport property.

Note that the present invention includes, in its scope, electronic devices and lighting devices including light-emitting devices, as well as light-emitting devices including light-emitting elements. The light-emitting device in this specification refers to an image display device and a light source (e.g., a lighting device). In addition, the light-emitting device includes all the following modules: a module in which a connector, such as a flexible printed circuit (FPC) or a tape carrier package (TCP), is attached to a light-emitting device; a module in which a printed wiring board is provided at the end of a TCP; and a module in which an integrated circuit (IC) is directly mounted on a light-emitting element by a chip-on-glass (COG) method.

One embodiment of the present invention has a structure in which an exciplex (excited complex) is formed in a light-emitting layer of a light-emitting element. With this structure, the generation probability of S1 in the formed exciplex can be more than or equal to the theoretical value (25%); accordingly, a light-emitting element with high emission efficiency can be achieved.

### BRIEF DESCRIPTION OF THE DRAWINGS

In the accompanying drawings:

FIG. 1 illustrates a concept of one embodiment of the present invention;

FIG. 2 illustrates a structure of a light-emitting element;

FIG. 3 illustrates a structure of a light-emitting element;

FIGS. 4A and 4B illustrate structures of a light-emitting element;

FIGS. 5A and 5B illustrate a light-emitting device;

FIGS. 6A to 6D illustrate electronic devices;

FIGS. 7A to 7C illustrate an electronic device;

FIG. 8 illustrates a lighting device;

FIG. 9 illustrates a structure of a light-emitting element;

FIG. 10 is a graph showing luminance-voltage characteristics of a light-emitting element 1 and a light-emitting element 2;

FIG. 11 is a graph showing luminance-external quantum efficiency characteristics of the light-emitting element 1 and the light-emitting element 2;

FIG. 12 is a graph showing emission spectra of the light-emitting element 1 and the light-emitting element 2;

FIG. 13 is a graph showing luminance-voltage characteristic of a light-emitting element 3 and a light-emitting element 4;

FIG. 14 is a graph showing luminance-external quantum efficiency characteristics of the light-emitting element 3 and the light-emitting element 4;

FIG. 15 is a graph showing emission spectra of the light-emitting element 3 and the light-emitting element 4;

FIG. 16 is a graph showing luminance-voltage characteristic of a light-emitting element 5 and a light-emitting element 6;

FIG. 17 is a graph showing luminance-external quantum efficiency characteristics of the light-emitting element 5 and the light-emitting element 6;

FIG. 18 is a graph showing emission spectra of the light-emitting element 5 and the light-emitting element 6;

FIG. 19 is a graph showing reliability of the light-emitting element 6;

FIG. 20 is a graph showing luminance-voltage characteristic of a light-emitting element 7, a light-emitting element 8, and a light-emitting element 9;

FIG. 21 is a graph showing luminance-external quantum efficiency characteristics of the light-emitting element 7, the light-emitting element 8, and the light-emitting element 9; and

FIG. 22 is a graph showing emission spectra of the light-emitting element 7, the light-emitting element 8, and the light-emitting element 9.

### DETAILED DESCRIPTION OF THE INVENTION

Embodiments of the present invention will be described in detail with reference to the drawings. Note that the present invention is not limited to the following description, and various changes and modifications can be made without departing from the spirit and scope of the invention. Therefore, the present invention should not be construed as being limited to the description in the following embodiments.

### Embodiment 1

In Embodiment 1, a concept in forming a light-emitting element that utilizes an exciplex (excited complex), which is one embodiment of the present invention, and a specific structure of the light-emitting element are described.

A light-emitting element of one embodiment of the present invention includes a light-emitting layer between a pair of electrodes. The light-emitting layer includes a first organic compound having an electron-transport property and a second organic compound having a p-phenylenediamine skeleton.

In this case, the first organic compound having an electron-transport property and the second organic compound having a p-phenylenediamine skeleton are a combination that forms an exciplex when they are in an excited state.

A light-emitting element of another embodiment of the present invention includes a light-emitting layer between a pair of electrodes. The light-emitting layer includes a first organic compound having an electron-transport property and a second organic compound having a 4-(9H-carbazol-9-yl)aniline skeleton.

In this case, the first organic compound having an electron-transport property and the second organic compound having a 4-(9H-carbazol-9-yl)aniline skeleton are a combination that forms an exciplex when they are in an excited state.

A light-emitting element of another embodiment of the present invention includes a light-emitting layer between a pair of electrodes. The light-emitting layer includes a first organic compound having an electron-transport property and a second organic compound having a 9-aryl-9H-carbazol-3-amine skeleton.

In this case, the first organic compound having an electron-transport property and the second organic compound having a 9-aryl-9H-carbazol-3-amine skeleton are a combination that forms an exciplex when they are in an excited state. This structure can achieve the highest external quantum efficiency among the structures described in Embodiment 1; accordingly, it is preferable to use a material having a 9-aryl-9H-carbazol-3-amine skeleton as the second organic compound.

A light-emitting element of another embodiment of the present invention includes a light-emitting layer between a pair of electrodes. The light-emitting layer includes a first organic compound having an electron-transport property and a second organic compound having a skeleton represented by General Formula (G1).

In this case, the first organic compound having an electron-transport property and the second organic compound having the skeleton represented by General Formula (G1), which are included in the light-emitting layer, are a combination that forms an exciplex when they are in an excited state.

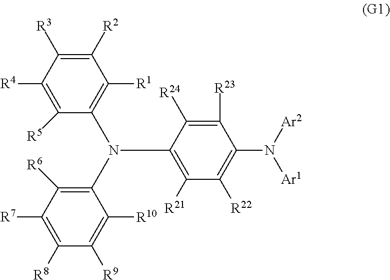

In the formula, R¹ to R^{1′} independently represent hydrogen, an alkyl group having 1 to 4 carbon atoms, a phenyl group, or a biphenyl group; R²¹ to R²⁴ independently represent hydrogen or an alkyl group having 1 to 4 carbon atoms; Ar¹ and Ar² independently represent a phenyl group, a biphenyl group, a fluorenyl group, a spirofluorenyl group, or a carbazolyl group, which is substituted or unsubstituted; when Ar¹ and Ar² include a substituent, the substituent is independently an alkyl group having 1 to 4 carbon atoms, a phenyl group, a biphenyl group, a 9-arylcarbazolyl group having 18 to 30 carbon atoms, or a diarylamino group having 12 to 60 carbon atoms; R¹ and R²⁴, R⁵ and R⁶, R¹⁰ and R²¹, R²² and Ar¹, and Ar² and R²³ may form a single bond therebetween.

Here, the formation process of an exciplex in one embodiment of the present invention is described. The formation process can be either of the following two processes.

One formation process is the process in which an exciplex is formed from the first organic compound having an electron-transport property (e.g., a host material) and the second organic compound having the skeleton represented by General Formula (G1) which are in the state of having carriers (cation or anion). In this formation process, formation of a singlet exciton from the first organic compound and the second organic compound can be suppressed; accordingly, a light-emitting element with long lifetime can be achieved.

The other formation process is an elementary process in which one of the first organic compound having an electron-transport property (e.g., host material) and the second organic compound having the skeleton represented by General Formula (G1) forms a singlet exciton and then the singlet exciton interacts with the other in the ground state to form an exciplex. In this process, although a singlet excited state of the first organic compound or the second organic compound is temporarily generated, the singlet excited state is rapidly converted into an exciplex. Therefore, deactivation of the singlet excited energy, reaction from the singlet excited state, or the like can be suppressed in this process as well. Accordingly, a light-emitting element with long lifetime can be achieved.

Note that the light-emitting element in the present invention includes both of the exciplexes formed in the above two formation processes.

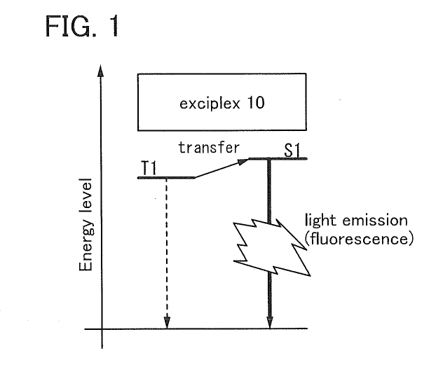

Next, the levels of the exciplex formed through the above-described formation processes and a process leading to light emission will be described with reference to FIG. 1. As illustrated in FIG. 1, the S1 level and the T1 level of an exciplex 10 formed in a light-emitting layer of a light-emitting element are positioned extremely close to each other compared to the S1 level and the T1 level of the respective substances (the first organic compound and the second organic compound) before the formation of the exciplex, which facilitates transfer of part of energy in T1 of the exciplex 10 to S1 due to thermal energy. Since the excitation lifetime of T1 of the exciplex 10 is long, part of energy of the exciplex 10 in T1 easily transfers to S1 without thermal deactivation. Thus, even when the theoretical generation probability of S1 right after recombination of carriers is 25%, the above-described process allows more S1 to be generated at the end. The exciton converted from T1 to S1 by reverse intersystem crossing also contributes to light emission from S1 of the exciplex; accordingly, the theoretical external quantum efficiency can be 5% or more (the generation probability of S1 (25%)×light extraction efficiency (20%)). In other words, the internal quantum efficiency can exceed 25% which is the theoretical limit of the element using a fluorescent material.

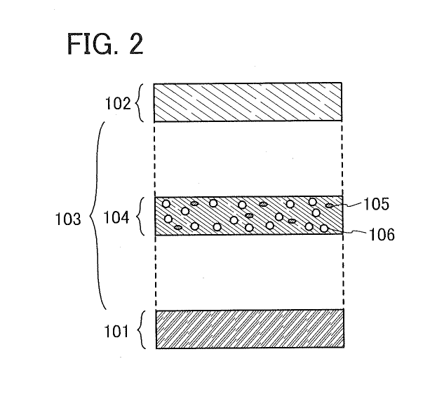

Next, an element structure of a light-emitting element of one embodiment of the present invention is described with reference to FIG. 2.

As illustrated in FIG. 2, the light-emitting element of one embodiment of the present invention has a structure in which a light-emitting layer 104 including a first organic compound and a second organic compound is provided between a pair of electrodes (an anode 101, a cathode 102). A light-emitting layer 104 is a part of a functional layer forming an EL layer 103 that is in contact with the pair of electrodes. The EL layer 103 can include not only the light-emitting layer 104 but also an appropriately selected layer in a desired position, such as a hole-injection layer, a hole-transport layer, an electron-transport layer, or an electron-injection layer. The light-emitting layer 104 includes a first organic compound 105 having an electron-transport property and a second organic compound 106 having the skeleton represented by General Formula (G1).

As the first organic compound 105 having an electron-transport property, an electron-transport material having an electron mobility of 10⁻⁶ cm²/Vs or higher can be used mainly. Specifically, a n-electron deficient heteroaromatic compound such as a nitrogen-containing heteroaromatic compound is preferable, and for example, the following compounds can be used: heterocyclic compounds having polyazole skeletons, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), and 2-[3-(dibenzothiophen-4-yl)phenyl]-1-phenyl-1H-benzimidazole (abbreviation: mDBTBIm-II); heterocyclic compounds having quinoxaline skeletons or dibenzoquinoxaline skeletons, such as 2-[3-(dibenzothiophen-4-yl)phenyl]dibenzo[f,h]quinoxaline (abbreviation: 2mDBTPDBq-II), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 2-[3′-(dibenzothiophen-4-yl)biphenyl-3-yl]dibenzo[f,h]quinoxaline (abbreviation: 2mDBTBPDBq-II), and 2-[3′-(9H-carbazol-9-yl)biphenyl-3-yl]dibenzo[f,h]quinoxaline (abbreviation: 2mCzBPDBq); heterocyclic compounds having diazine skeletons (pyrimidine skeletons or pyrazine skeletons), such as 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), and 4,6-bis[3-(9H-carbazol-9-yl)phenyl]pyrimidine (abbreviation: 4,6mCzP2Pm); and heterocyclic compounds having pyridine skeletons, such as 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), and 3,3′,5,5′-tetra[(m-pyridyl)-phen-3-yl]biphenyl (abbreviation: BP4mPy). Among the above-described compounds, the heterocyclic compounds having quinoxaline skeletons or dibenzoquinoxaline skeletons, the heterocyclic compounds having diazine skeletons, and the heterocyclic compounds having pyridine skeletons have favorable reliability and can preferably be used. The following can also be given as the first organic compound: triaryl phosphine oxides such as phenyl-di(1-pyrenyl)phosphine oxide (abbreviation: POPy₂), spiro-9,9′-bifluoren-2-yl-diphenylphosphine oxide (abbreviation: SPPO1), 2,8-bis(diphenylphosphoryl)dibenzo[b,d]thiophene (abbreviation: PPT), and 3-(diphenylphosphoryl)-9-[4-(diphenylphosphoryl)phenyl]-9H-carbazole (abbreviation: PPO21); and triaryl borane such as tris[2,4,6-trimethyl-3-(3-pyridyl)phenyl]borane (abbreviation: 3TPYMB).

As the second organic compound 106 having the skeleton represented by General Formula (G1), an organic compound having a skeleton represented by General Formula (G2) is particularly preferable. The organic compound having the skeleton represented by General Formula (G2) has a 9-aryl-9H-carbazol-3-amine skeleton, and in the case of using this compound as the second organic compound, particularly high external quantum efficiency can be achieved. In other words, the organic compound having the skeleton represented by General Formula (G2) is characteristic among the organic compounds having the skeleton represented by General Formula (G1).

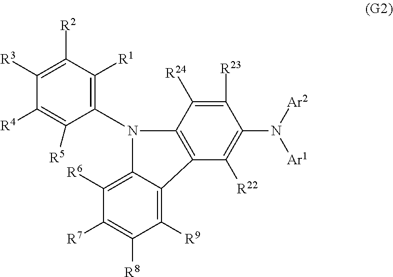

In the formula, R¹ to R⁹ independently represent hydrogen, an alkyl group having 1 to 4 carbon atoms, a phenyl group, or a biphenyl group; R²² to R²⁴ independently represent hydrogen or an alkyl group having 1 to 4 carbon atoms; Ar¹ and Ar² independently represent a phenyl group, a biphenyl group, a fluorenyl group, a spirofluorenyl group, or a carbazolyl group, which is substituted or unsubstituted; when Ar¹ and Ar² include a substituent, the substituent is independently an alkyl group having 1 to 4 carbon atoms, a phenyl group, a biphenyl group, a 9-arylcarbazolyl group having 18 to 30 carbon atoms, or a diarylamino group having 12 to 60 carbon atoms; R¹ and R²⁴, R⁵ and R⁶, R²² and Ar¹, and Ar² and R²³ may form a single bond therebetween.

Specifically, as the substance represented by General Formula (G2), 2-[N-(9-phenylcarbazol-3-yl)-N-phenylamino]-spiro-9,9′-bifluorene (abbreviation: PCASF) (Structural Formula 100), N,N-bis(9-phenyl-9H-carbazol-3-yl)-N,N-diphenyl-spiro-9,9′-bifluorene-2,7-diamine (abbreviation: PCA2SF) (Structural Formula 101), or the like can be used.

Specific examples of the substances represented by General Formula (G1) and General Formula (G2) as well as the above-mentioned PCASF (abbreviation) and PCA2SF (abbreviation) are shown below.

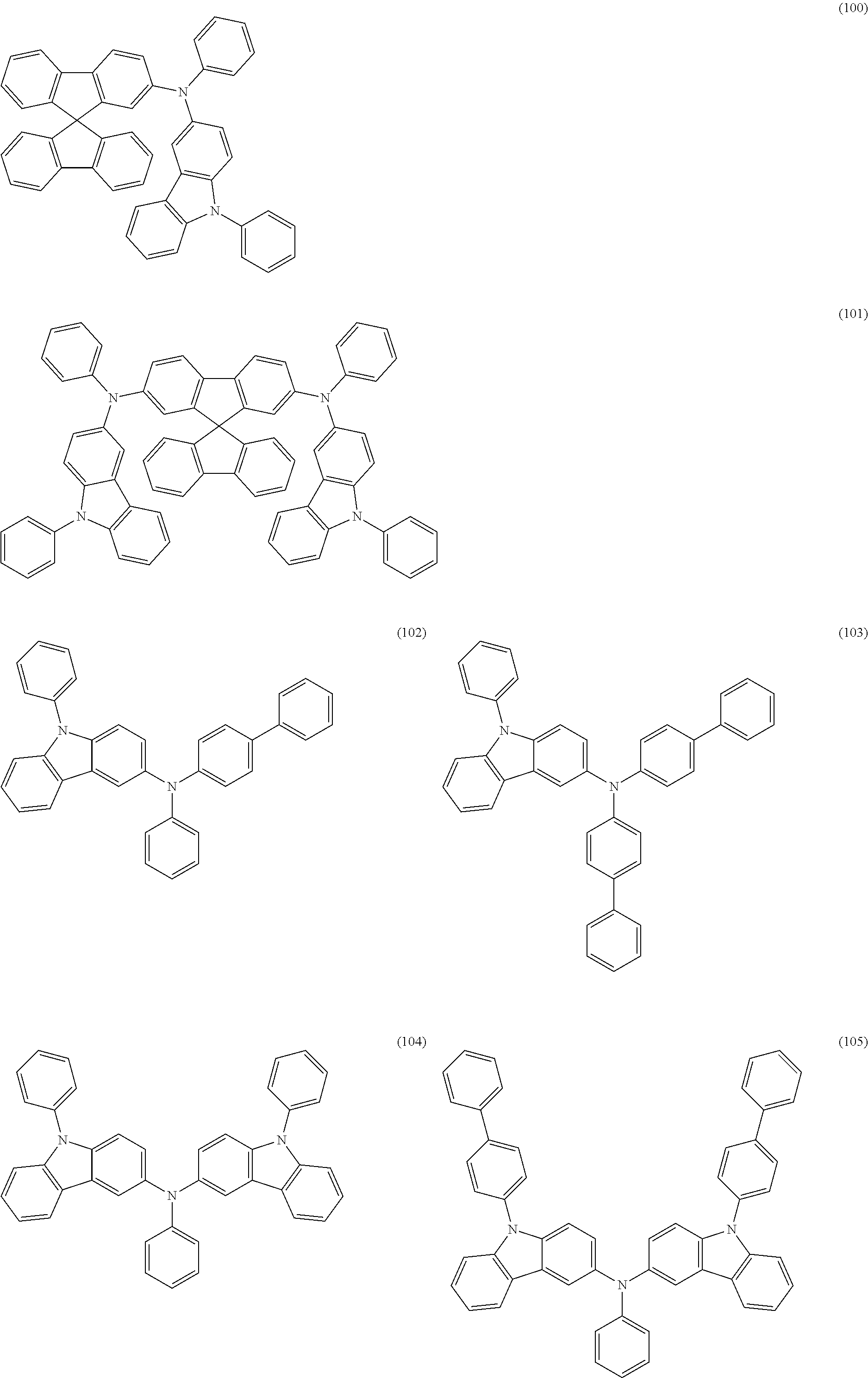

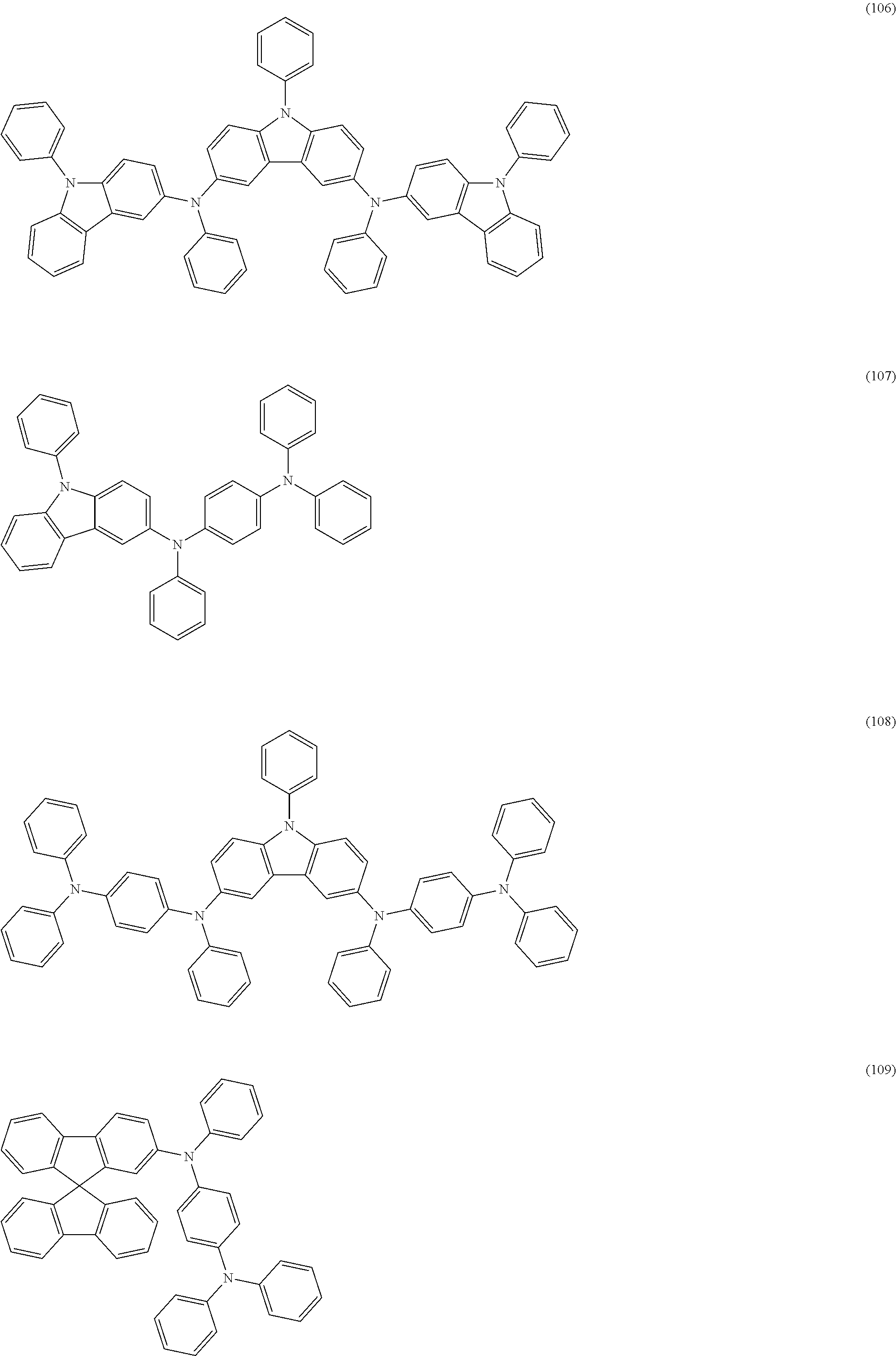

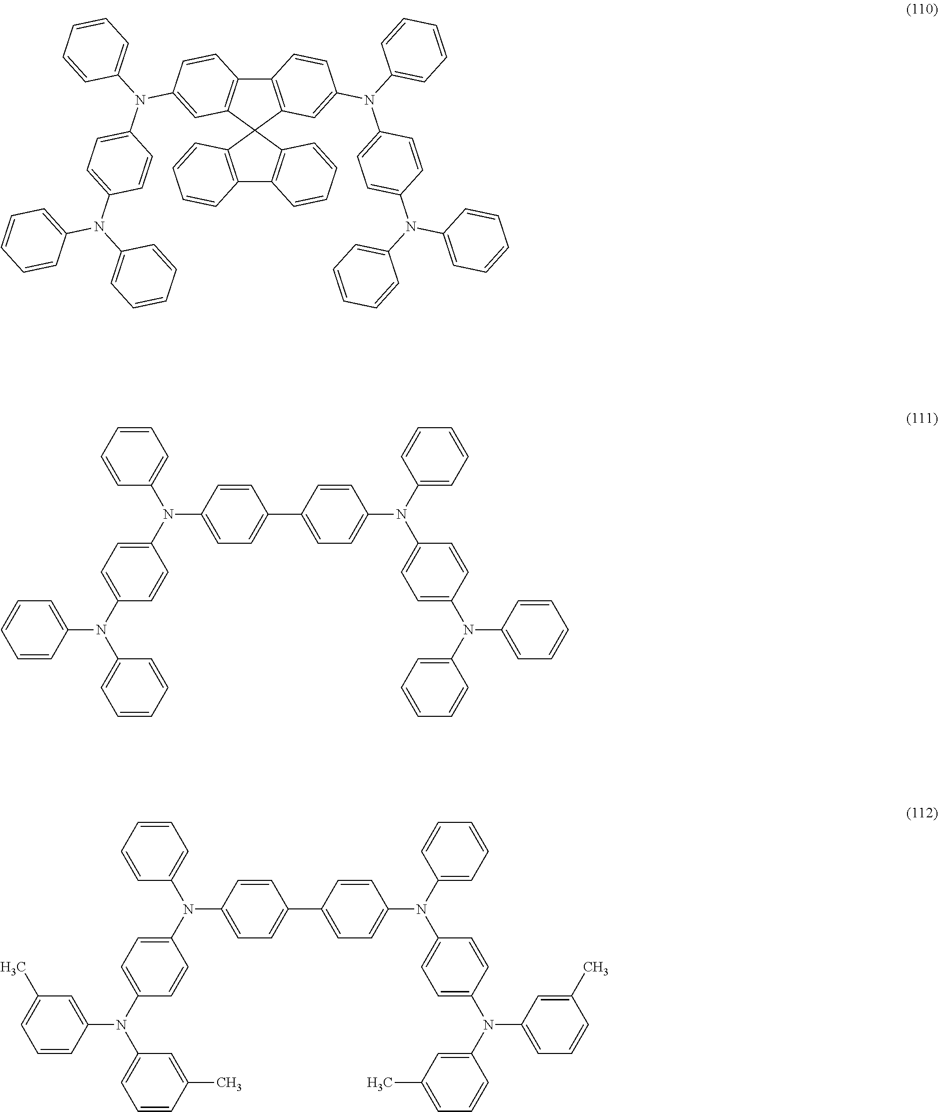

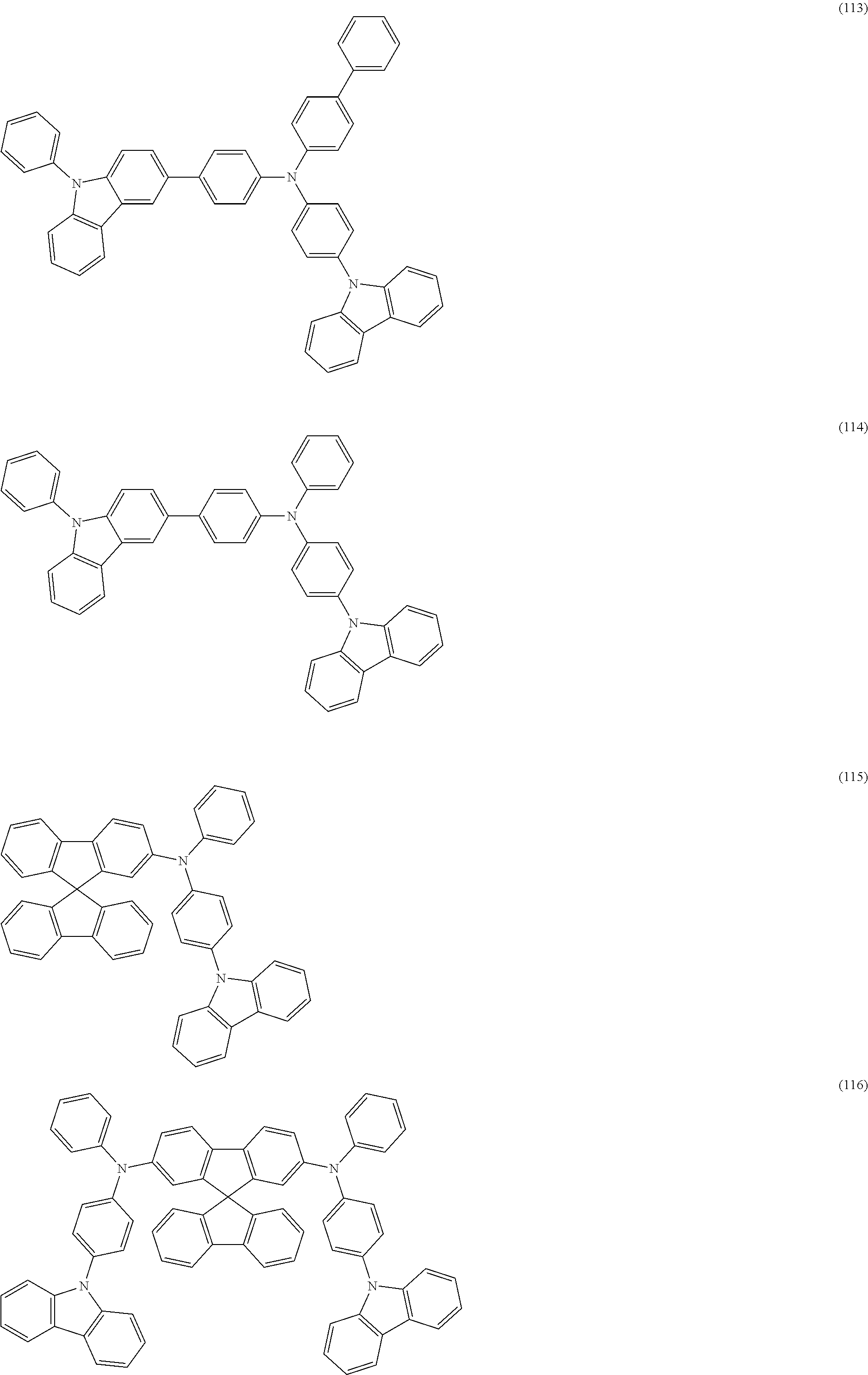

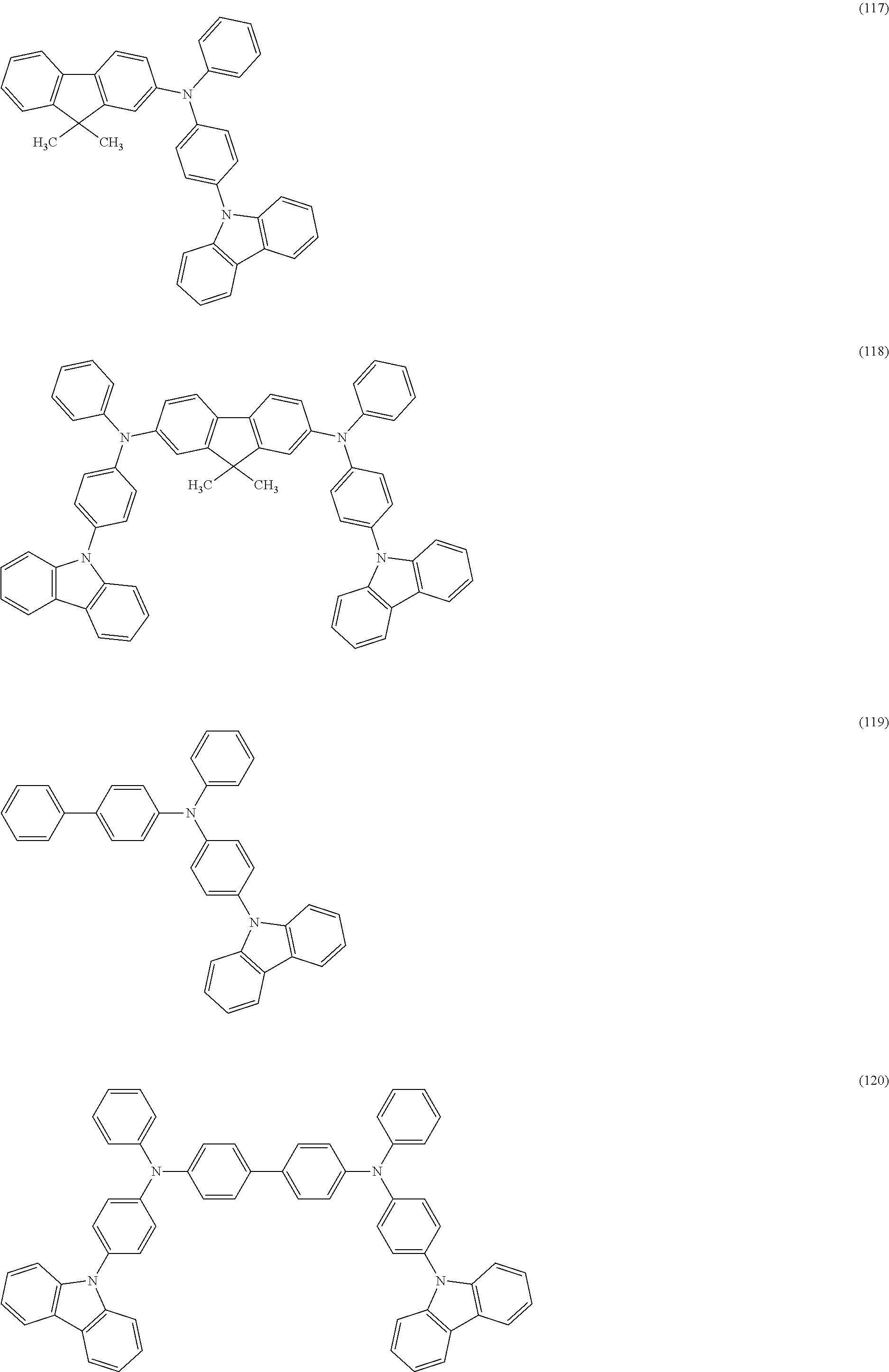

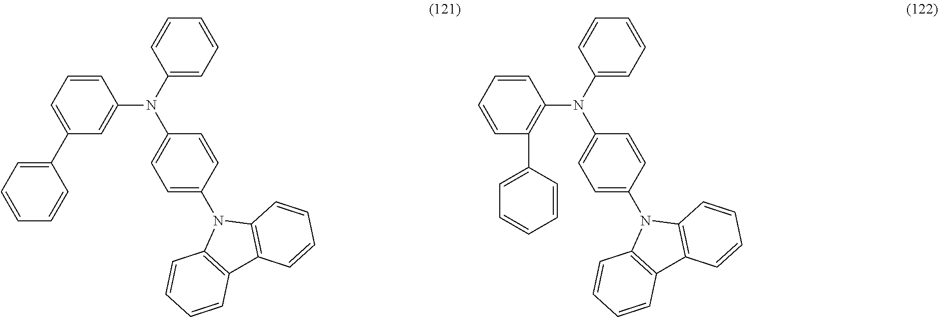

The first organic compound 105 having an electron-transport property and the second organic compound having the skeleton represented by General Formula (G1) are not limited to the above-described substances as long as they are a combination that can form an exciplex and easily causes transfer of part of energy in T1 of the exciplex to S1.

In this embodiment, an exciplex (excited complex) is formed in a light-emitting layer of a light-emitting element. The generation probability of S1 in the formed exciplex can be more than or equal to the theoretical value (25%); accordingly, a light-emitting element with high emission efficiency can be achieved.

### Embodiment 2

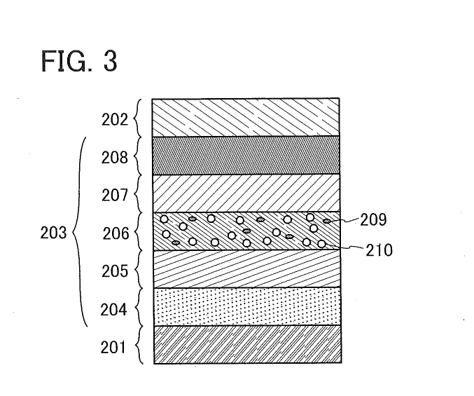

In this embodiment, an example of a light-emitting element of one embodiment of the present invention is described with reference to FIG. 3.

In the light-emitting element described in this embodiment, as illustrated in FIG. 3, an EL layer 203 including a light-emitting layer 206 is provided between a pair of electrodes (a first electrode (anode) 201 and a second electrode (cathode) 202), and the EL layer 203 includes a hole-injection layer 204, a hole-transport layer 205, an electron-transport layer 207, an electron-injection layer 208, and the like in addition to the light-emitting layer 206.

The light-emitting layer 206 includes the first organic compound having an electron-transport property and the second organic compound having the skeleton represented by General Formula (G1), as in the light-emitting element described in Embodiment 1. Note that the same substances described in Embodiment 1 can be used as the first organic compound having an electron-transport property and the second organic compound having the skeleton represented by General Formula (G1), and description thereof is omitted.

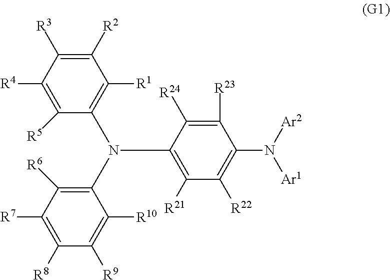

In the formula, R¹ to R¹⁰ independently represent hydrogen, an alkyl group having 1 to 4 carbon atoms, a phenyl group, or a biphenyl group; R²¹ to R²⁴ independently represent hydrogen or an alkyl group having 1 to 4 carbon atoms; Ar¹ and Ar² independently represent a phenyl group, a biphenyl group, a fluorenyl group, a spirofluorenyl group, or a carbazolyl group, which is substituted or unsubstituted; when Ar¹ and Ar² include a substituent, the substituent is independently an alkyl group having 1 to 4 carbon atoms, a phenyl group, a biphenyl group, a 9-arylcarbazolyl group having 18 to 30 carbon atoms, or a diarylamino group having 12 to 60 carbon atoms; R¹ and R²⁴, R⁵ and R⁶, R¹⁰ and R²¹, R²² and Ar¹, and Ar² and R²³ may form a single bond therebetween.

The light-emitting layer 206 may further include, in addition to the first organic compound and the second organic compound for forming an exciplex, a light-emitting substance that can convert energy from T1 of the exciplex formed in the light-emitting layer 206 into light emission (light-emitting substance that converts triplet excited energy into light emission).

The exciplex in one embodiment of the present invention has a feature of having an extremely small energy difference between the S1 level and the T1 level. Therefore, by making a large overlap between the emission spectrum of the exciplex formed in the light-emitting layer 206 and the absorption spectrum of the light-emitting substance that converts triplet excited energy into light emission, not only energy in T1 but also energy in S1 in the exciplex can be transferred efficiently to the light-emitting substance that converts triplet excited energy into light emission. As a result, emission efficiency of the light-emitting element can be increased significantly. Further in this structure, by setting the difference between an emission peak wavelength of the exciplex and an emission peak wavelength of the light-emitting substance that converts triplet excited energy into light emission at 0.1 eV or less, a light emission start voltage that is lower than the conventional one as well as high emission efficiency can be achieved. This structure has a feature that enables a reduction in voltage without sacrificing efficiency even when the peak wavelength of the exciplex is equal to or longer than the emission peak wavelength of the light-emitting substance that converts triplet excited energy into light emission.

Note that as the light-emitting substance that converts triplet excited energy into light emission, a phosphorescent compound (e.g., an organometallic complex), a thermally activated delayed fluorescence (TADF) material, or the like is preferably used.

Note that examples of the organometallic complex include bis[2-(4′,6′-difluorophenyl)pyridinato-N, C²′]iridium(III) tetrakis(1-pyrazolyl)borate (abbreviation: FIr6), bis[2-(4′,6′-difluorophenyl)pyridinato-N,C²′]iridium(III) picolinate (abbreviation: FIrpic), bis[2-(3′,5′-bistrifluoromethylphenyl)pyridinato-N,C²′]iridium(III) picolinate (abbreviation: Ir(CF₃ppy)₂(pic)), bis[2-(4′,6′-difluorophenyl)pyridinato-N,C²′]iridium(III) acetylacetonate (abbreviation: FIracac), tris(2-phenylpyridinato)iridium(III) (abbreviation: Ir(ppy)₃), bis(2-phenylpyridinato)iridium(III) acetylacetonate (abbreviation: Ir(ppy)₂(acac)), bis(benzo[h]quinolinato)iridium(III) acetylacetonate (abbreviation: Ir(bzq)₂(acac)), bis(2,4-diphenyl-1,3-oxazolato-N, C²′)iridium(III) acetylacetonate (abbreviation: Ir(dpo)₂(acac)), bis {2-[4′-(perfluorophenyl)phenyl]pyridinato-N, C²′}iiridium(III) acetylacetonate (abbreviation: Ir(p-PF-ph)₂(acac)), bis(2-phenylbenzothiazolato-N,C²′)iridium(III) acetylacetonate (abbreviation: Ir(bt)₂(acac)), bis[2-(2′-benzo[4,5-c]thienyl)pyridinato-N,C³′]iridium(III) acetylacetonate (abbreviation: Ir(btp)₂(acac)), bis(1-phenylisoquinolinato-N,C²′)iridium(III) acetylacetonate (abbreviation: Ir(piq)₂(acac)), (acetylacetonato)bis[2,3-bis(4-fluorophenyl)quinoxalinato]iridium(III) (abbreviation: Ir(Fdpq)₂(acac)), (acetylacetonato)bis(2,3,5-triphenylpyrazinato)iridium(III) (abbreviation: Ir(tppr)₂(acac)), 2,3,7,8,12,13,17,18-octaethyl-21H,23H-porphyrin platinum(II) (abbreviation: PtOEP), tris(acetylacetonato) (monophenanthroline)terbium(III) (abbreviation: Tb(acac)₃(Phen)), tris(1,3-diphenyl-1,3-propanedionato) (monophenanthroline)europium(III) (abbreviation: Eu(DBM)₃(Phen)), and tris[1-(2-thenoyl)-3,3,3-trifluoroacetonato](monophenanthroline)europium(III) (abbreviation: Eu(TTA)₃(Phen)).

Next, a specific example in manufacturing the light-emitting element described in this embodiment is described.

For the first electrode (anode) 201 and the second electrode (cathode) 202, a metal, an alloy, an electrically conductive compound, a mixture thereof, or the like can be used. Specifically, indium oxide-tin oxide (ITO: indium tin oxide), indium oxide-tin oxide containing silicon or silicon oxide, indium oxide-zinc oxide (indium zinc oxide), indium oxide containing tungsten oxide and zinc oxide, gold (Au), platinum (Pt), nickel (Ni), tungsten (W), chromium (Cr), molybdenum (Mo), iron (Fe), cobalt (Co), copper (Cu), palladium (Pd), or titanium (T1) can be used. In addition, an element belonging to Group 1 or Group 2 of the periodic table, for example, an alkali metal such as lithium (Li) or cesium (Cs), an alkaline earth metal such as magnesium (Mg), calcium (Ca), or strontium (Sr), an alloy containing such an element (e.g., MgAg or AlLi), a rare earth metal such as europium (Eu) or ytterbium (Yb), an alloy containing such an element, graphene, or the like can be used. The first electrode (anode) 201 and the second electrode (cathode) 202 can be formed by, for example, a sputtering method, an evaporation method (including a vacuum evaporation method), or the like.

Examples of a substance having a high hole-transport property which is used for the hole-injection layer 204 and the hole-transport layer 205 include aromatic amine compounds such as 4,4′-bis[N-(1-naphthyl)-N-phenylamino]biphenyl (abbreviation: NPB or α-NPD), N,N′-bis(3-methylphenyl)-N,N′-diphenyl-[1,1′-biphenyl]-4,4′-diamine (abbreviation: TPD), 4,4′,4″-tris(carbazol-9-yl)triphenylamine (abbreviation: TCTA), 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), and 4,4′-bis[N-(spiro-9,9′-bifluoren-2-yl)-N-phenylamino]biphenyl (abbreviation: BSPB), 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), and 3-[N-(1-naphthyl)-N-(9-phenylcarbazol-3-yl)amino]-9-phenylcarbazole (abbreviation: PCzPCN1). Alternatively, the following carbazole derivative can be used: 4,4′-di(N-carbazolyl)biphenyl (abbreviation: CBP), 1,3,5-tris[4-(N-carbazolyl)phenyl]benzene (abbreviation: TCPB), and 9-[4-(10-phenyl-9-anthracenyl)phenyl]-9H-carbazole (abbreviation: CzPA). The substances mentioned here are mainly substances having a hole mobility of 10⁻⁶ cm²/Vs or higher. However, substances other than the above described substances may also be used as long as the substances have higher hole-transport properties than electron-transport properties.

Still other examples include high molecular compounds such as poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N-phenylamino}phenyl)methacrylamide] (abbreviation: PTPDMA), and poly[N,N-bis(4-butylphenyl)-N,N′-bis(phenyl)benzidine] (abbreviation: Poly-TPD).

Further, examples of an acceptor substance which can be used in the hole-injection layer 204 include oxides of transition metals, oxides of metals belonging to Groups 4 to 8 of the periodic table, and the like. Specifically, molybdenum oxide is particularly preferable.

As described above, the light-emitting layer 206 includes a first organic compound 209 having an electron-transport property and a second organic compound 210 having the skeleton represented by General Formula (G1) and may further include a light-emitting substance that converts triplet excited energy into light emission.

Note that it is preferable to use, as a material of the hole-transport layer 205 in contact with the light-emitting layer 206, the compound that can be used as the second organic compound, that is, any of an organic compound having a p-phenylenediamine skeleton, an organic compound having a 4-(9H-carbazol-9-yl)aniline skeleton, and an organic compound having a 9-aryl-9H-carbazol-3-amine skeleton. More specifically, it is preferable to use the organic compound represented by General Formula (G1) or (G2). With this structure, the hole-injection barrier between the hole transport layer 205 and the light-emitting layer 206 can be reduced, which can not only increase emission efficiency but also reduce driving voltage. Thus, a light-emitting element having a small decrease in power efficiency due to loss of voltage even in the case of emitting light with high luminance can be obtained. A particularly preferable mode in terms of the hole-injection barrier is a structure in which the hole-transport layer 205 includes the same organic compound as the second organic compound.

The electron-transport layer 207 is a layer that contains a substance having a high electron-transport property. For the electron-transport layer 207, it is possible to use a metal complex such as Alq₃, tris(4-methyl-8-quinolinolato)aluminum (abbreviation: Almq₃), bis(10-hydroxybenzo[h]quinolinato)beryllium (abbreviation: BeBq₂), BAlq, Zn(BOX)₂, or bis[2-(2-hydroxyphenyl)benzothiazolato]zinc (abbreviation: Zn(BTZ)₂). Alternatively, a heteroaromatic compound such as 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), 3-(4-tert-butylphenyl)-4-phenyl-5-(4-biphenylyl)-1,2,4-triazole (abbreviation: TAZ), 3-(4-tert-butylphenyl)-4-(4-ethylphenyl)-5-(4-biphenylyl)-1,2,4-triazole (abbreviation: p-EtTAZ), bathophenanthroline (abbreviation: BPhen), bathocuproine (abbreviation: BCP), or 4,4′-bis(5-methylbenzoxazol-2-yl)stilbene (abbreviation: BzOs) can also be used. Further alternatively, a high molecular compound such as poly(2,5-pyridinediyl) (abbreviation: PPy), poly[(9,9-dihexylfluorene-2,7-diyl)-co-(pyridine-3,5-diyl)](abbreviation: PF-Py) or poly[(9,9-dioctylfluorene-2,7-diyl)-co-(2,2′-bipyridine-6,6′-diyl)] (abbreviation: PF-BPy) can be used. The substances mentioned here are mainly substances having an electron mobility of 10⁶ cm²/Vs or higher. However, substances other than the above described substances may also be used in the electron-transport layer 207 as long as the substances have higher electron-transport properties than hole-transport properties.

The electron-transport layer 207 is not limited to a single layer, and may be a stack of two or more layers containing any of the above-described substances.

The electron-injection layer 208 is a layer that contains a substance having a high electron-injection property. Examples of the material of the electron-injection layer 208 include alkali metals, alkaline earth metals, and compounds thereof, such as lithium fluoride (LiF), cesium fluoride (CsF), calcium fluoride (CaF₂), and lithium oxide (LiOₓ), and rare earth metal compounds, such as erbium fluoride (ErF₃). Further alternatively, any of the above-described substances that are used to form the electron-transport layer 207 can be used.

Alternatively, a composite material in which an organic compound and an electron donor (a donor) are mixed may be used for the electron-injection layer 208. Such a composite material is excellent in an electron-injection property and an electron-transport property because electrons are generated in the organic compound by the electron donor. The organic compound here is preferably a material excellent in transporting the generated electrons, and specifically any of the above substances (such as metal complexes and heteroaromatic compounds) for the electron-transport layer 207 can be used. As the electron donor, a substance showing an electron-donating property with respect to the organic compound may be used. Specifically, an alkali metal, an alkaline earth metal, and a rare earth metal are preferable, and lithium, cesium, magnesium, calcium, erbium, ytterbium, and the like are given. In addition, alkali metal oxide or alkaline earth metal oxide such as lithium oxide, calcium oxide, barium oxide, and the like can be given. A Lewis base such as magnesium oxide can alternatively be used. An organic compound such as tetrathiafulvalene (abbreviation: TTF) can alternatively be used.

Note that the hole-injection layer 204, the hole-transport layer 205, the light-emitting layer 206, the electron-transport layer 207, and the electron-injection layer 208 which are mentioned above can each be formed by a method such as an evaporation method (including a vacuum evaporation method), an inkjet method, or a coating method.

Light emission from the light-emitting layer 206 of the above-described light-emitting element is extracted to the outside through either the first electrode 201 or the second electrode 202 or both of them. Therefore, either the first electrode 201 or the second electrode 202 in this embodiment, or both of them, is an electrode having a light-transmitting property.

In this embodiment, an exciplex (excited complex) is formed in a light-emitting layer of a light-emitting element. The generation probability of S1 in the formed exciplex can be more than or equal to the theoretical value (25%); accordingly, a light-emitting element with high emission efficiency can be achieved.

Note that the light-emitting element described in this embodiment is one embodiment of the present invention and is particularly characterized by the structure of the light-emitting layer. Therefore, when the structure described in this embodiment is employed, a passive matrix light-emitting device, an active matrix light-emitting device, and the like can be manufactured. These light-emitting devices are each included in the present invention.

Note that there is no particular limitation on the structure of the TFT in the case of manufacturing the active matrix light-emitting device. For example, a staggered TFT or an inverted staggered TFT can be used as appropriate. Further, a driver circuit formed over a TFT substrate may be formed using either an n-channel TFT or a p-channel TFT or both of them. Furthermore, there is no particular limitation on the crystallinity of a semiconductor film used for the TFT. For example, an amorphous semiconductor film, a crystalline semiconductor film, an oxide semiconductor film, or the like can be used.

Note that the structure described in this embodiment can be used in combination with any of the structures described in the other embodiments, as appropriate.

### Embodiment 3

In this embodiment, as one embodiment of the present invention, a light-emitting element (hereinafter referred to as tandem light-emitting element) in which a charge generation layer is provided between a plurality of EL layers will be described.

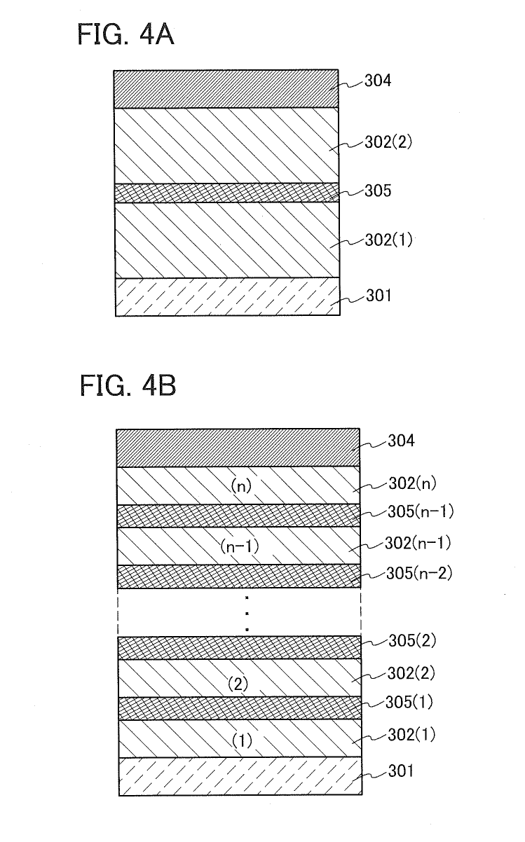

A light-emitting element described in this embodiment is a tandem light-emitting element including a plurality of EL layers (a first EL layer 302(1) and a second EL layer 302(2)) between a pair of electrodes (a first electrode 301 and a second electrode 304) as illustrated in FIG. 4A.

In this embodiment, the first electrode 301 functions as an anode, and the second electrode 304 functions as a cathode. Note that the first electrode 301 and the second electrode 304 can have structures similar to those in Embodiment 1. In addition, although the plurality of EL layers (the first EL layer 302(1) and the second EL layer 302(2)) may have a structure similar to that of the EL layer described in Embodiment 1 or 2, any of the EL layers may have a structure similar to that of the EL layer described in Embodiment 1 or 2. In other words, the structures of the first EL layer 302(1) and the second EL layer 302(2) may be the same or different from each other and can be similar to those of the EL layer described in Embodiment 1 or 2.

A charge generation layer 305 is provided between the EL layers (the first EL layer 302(1) and the second EL layer 302(2)). The charge generation layer 305 has a function of injecting electrons into one of the EL layers and injecting holes into the other of the EL layers when a voltage is applied between the first electrode 301 and the second electrode 304. In this embodiment, when a voltage is applied so that the first electrode 301 has higher potential than the second electrode 304, the charge generation layer 305 injects electrons into the first EL layer 302(1) and injects holes into the second EL layer 302(2).

Note that in terms of light extraction efficiency, the charge generation layer 305 preferably has a light-transmitting property with respect to visible light (specifically, the charge generation layer 305 preferably has a visible light transmittance of 40% or more). Further, the charge generation layer 305 functions even if it has lower conductivity than the first electrode 301 or the second electrode 304.

The charge generation layer 305 may have either a structure in which an electron acceptor (acceptor) is added to an organic compound having a high hole-transport property or a structure in which an electron donor (donor) is added to an organic compound having a high electron-transport property. Alternatively, both of these structures may be stacked.

In the case of the structure in which an electron acceptor is added to an organic compound having a high hole-transport property, as the organic compound having a high hole-transport property, for example, an aromatic amine compound such as NPB, TPD, TDATA, MTDATA, or 4,4′-bis[N-(spiro-9,9′-bifluoren-2-yl)-N-phenylamino]biphenyl (abbreviation: BSPB), or the like can be used. The substances mentioned here are mainly ones that have a hole mobility of 10⁻⁶ cm²/Vs or higher. Note that substances other than the above substances may be used as long as they are organic compounds with a hole-transport property higher than an electron-transport property.

Further, as the electron acceptor, a halogen compound such as 7,7,8,8-tetracyano-2,3,5,6-tetrafluoroquinodimethane (abbreviation: F₄-TCNQ) or chloranil; a cyano compound such as pirazino[2,3-f][1,10]phenanthroline-2,3-dicarbonitrile (abbreviation: PPDN) or dipyrazino[2,3-f:2′,3′-h]quinoxaline-2,3,6,7,10,11-hexacarbonitrile (abbreviation: HAT-CN); or the like can be used. Alternatively, a transition metal oxide can be used. Further alternatively, an oxide of metals that belong to Group 4 to Group 8 of the periodic table can be used. Specifically, vanadium oxide, niobium oxide, tantalum oxide, chromium oxide, molybdenum oxide, tungsten oxide, manganese oxide, and rhenium oxide are preferable because their electron-accepting property is high. Among these, molybdenum oxide is especially preferable because it is stable in the air, has a low hygroscopic property, and is easily handled.

On the other hand, in the case of the structure in which an electron donor is added to an organic compound having a high electron-transport property, as the organic compound having a high electron-transport property for example, a metal complex having a quinoline skeleton or a benzoquinoline skeleton, such as Alq, Almq₃, BeBq₂, or BAlq, or the like can be used. Alternatively, it is possible to use a metal complex having an oxazole-based ligand or a thiazole-based ligand, such as Zn(BOX)₂ or Zn(BTZ)₂. Further alternatively, instead of a metal complex, it is possible to use PBD, OXD-7, TAZ, BPhen, BCP, or the like. The substances mentioned here are mainly ones that have an electron mobility of 10⁻⁶ cm²/Vs or higher. Note that substances other than the above substances may be used as long as they are organic compounds having an electron-transport property higher than a hole-transport property.

As the electron donor, it is possible to use an alkali metal, an alkaline earth metal, a rare earth metal, a metal belonging to Group 13 of the periodic table, or an oxide or a carbonate thereof. Specifically, it is preferable to use lithium (Li), cesium (Cs), magnesium (Mg), calcium (Ca), ytterbium (Yb), indium (In), lithium oxide, cesium carbonate, or the like. Alternatively, an organic compound such as tetrathianaphthacene may be used as the electron donor.

Note that forming the charge generation layer 305 by using any of the above materials can suppress an increase in drive voltage caused by the stack of the EL layers.

Although the light-emitting element having two EL layers has been described in this embodiment, the present invention can be similarly applied to a light-emitting element in which n EL layers (n is three or more) are stacked as illustrated in FIG. 4B. In the case where a plurality of EL layers are included between a pair of electrodes as in the light-emitting element according to this embodiment, by provision of a charge generation layer between the EL layers, light emission in a high luminance region can be obtained with current density kept low. Since the current density can be kept low, the element can have long lifetime. When the light-emitting element is applied for illumination, voltage drop due to resistance of an electrode material can be reduced, thereby achieving homogeneous light emission in a large area. Moreover, a light-emitting device having low driving voltage and lower power consumption can be obtained.

By making the EL layers emit light of different colors from each other, the light-emitting element can provide light emission of a desired color as a whole. For example, by forming a light-emitting element having two EL layers such that the emission color of the first EL layer and the emission color of the second EL layer are complementary colors, the light-emitting element can provide white light emission as a whole. Note that the word “complementary” means color relationship in which an achromatic color is obtained when colors are mixed. In other words, when light obtained from a light-emitting substance and light of a complementary color are mixed, white light emission can be obtained.

Further, the same can be applied to a light-emitting element having three EL layers. For example, the light-emitting element as a whole can provide white light emission when the emission color of the first EL layer is red, the emission color of the second EL layer is green, and the emission color of the third EL layer is blue.

In the structure described in this embodiment in which EL layers are stacked with a charge generation layer provided therebetween, by adjusting the distance between electrodes (the first electrode 301 and the second electrode 304), the light-emitting element can have a micro optical resonator (microcavity) structure utilizing a resonant effect of light.

Note that the structure described in this embodiment can be used in combination with any of the structures described in the other embodiments, as appropriate.

### Embodiment 4

In this embodiment, a light-emitting device including a light-emitting element which is one embodiment of the present invention will be described.

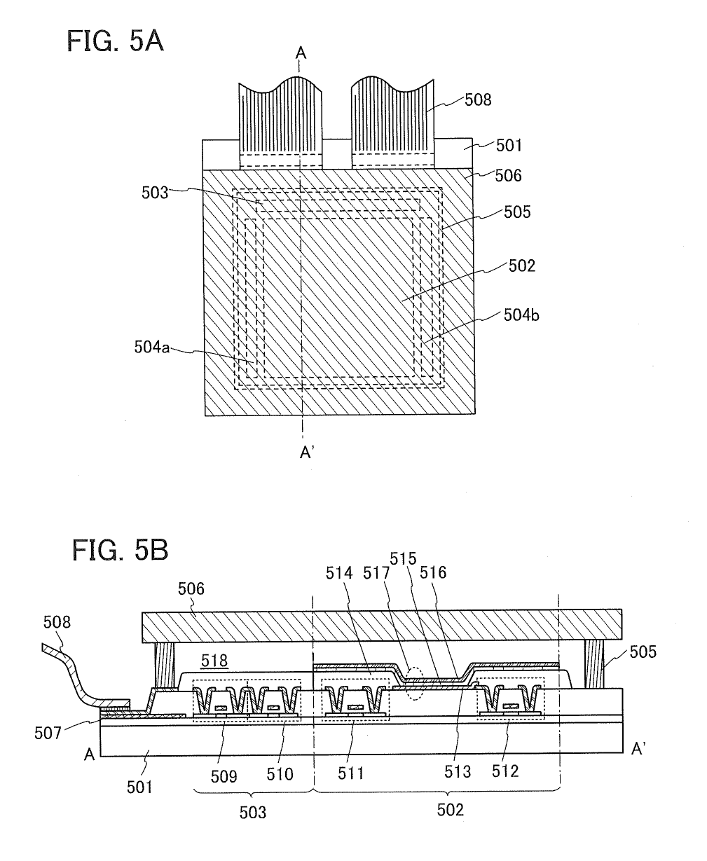

Note that any of the light-emitting elements described in the other embodiments can be applied to the light-emitting element. The light-emitting device can be either a passive matrix light-emitting device or an active matrix light-emitting device. In this embodiment, an active matrix light-emitting device is described with reference to FIGS. 5A and 5B.

Note that FIG. 5A is a top view illustrating the light-emitting device and FIG. 5B is a cross-sectional view taken along chain line A-A′ in FIG. 5A. The active matrix light-emitting device according to this embodiment includes a pixel portion 502 provided over an element substrate 501, a driver circuit portion (a source line driver circuit) 503, and driver circuit portions (gate line driver circuits) 504a and 504b. The pixel portion 502, the driver circuit portion 503, and the driver circuit portions 504a and 504b are sealed between the element substrate 501 and the sealing substrate 506 by a sealant 505.

In addition, a lead wiring 507 is provided over the element substrate 501. The lead wiring 507 is provided for connecting an external input terminal through which a signal (e.g., a video signal, a clock signal, a start signal, and a reset signal) or a potential from the outside is transmitted to the driver circuit portion 503 and the driver circuit portions 504a and 504b. Here is shown an example in which a flexible printed circuit (FPC) 508 is provided as the external input terminal. Although only the FPC is illustrated here, a printed wiring board (PWB) may be attached to the FPC. The light-emitting device in this specification includes, in its category, not only the light-emitting device itself but also the light-emitting device provided with the FPC or the PWB.

Next, a cross-sectional structure is described with reference to FIG. 5B. The driver circuit portions and the pixel portion are formed over the element substrate 501; here are illustrated the driver circuit portion 503 which is the source line driver circuit and the pixel portion 502.

The driver circuit portion 503 illustrates an example where a CMOS circuit is formed, which is a combination of an n-channel TFT 509 and a p-channel TFT 510. Note that a circuit included in the driver circuit portion may be formed using various CMOS circuits, PMOS circuits, or NMOS circuits. Although a driver integrated type in which the driver circuit is formed over the substrate is described in this embodiment, the driver circuit is not necessarily formed over the substrate, and the driver circuit can be formed outside, not over the substrate.

The pixel portion 502 is formed of a plurality of pixels each of which includes a switching TFT 511, a current control TFT 512, and a first electrode (anode) 513 which is electrically connected to a wiring (a source electrode or a drain electrode) of the current control TFT 512. Note that an insulator 514 is formed to cover end portions of the first electrode (anode) 513. In this embodiment, the insulator 514 is formed using a positive photosensitive acrylic resin.

The insulator 514 preferably has a curved surface with curvature at an upper end portion or a lower end portion thereof in order to obtain favorable coverage by a film which is to be stacked over the insulator 514. For example, in the case of using a positive photosensitive acrylic resin as a material for the insulator 514, the insulator 514 preferably has a curved surface with a curvature radius (0.2 μm to 3 μm) at the upper end portion. Note that the insulator 514 can be formed using either a negative photosensitive resin or a positive photosensitive resin. It is possible to use, without limitation to an organic compound, an inorganic compound such as silicon oxide or silicon oxynitride.

A light-emitting element 517 is formed by stacking an EL layer 515 and a second electrode (cathode) 516 over the first electrode (anode) 513. The EL layer 515 includes at least the light-emitting layer described in Embodiment 1. Further, in the EL layer 515, a hole-injection layer, a hole-transport layer, an electron-transport layer, an electron-injection layer, a charge-generation layer, and the like can be provided as appropriate in addition to the light-emitting layer.

For the first electrode (anode) 513, the EL layer 515, and the second electrode (cathode) 516, the materials described in Embodiment 2 can be used. Although not illustrated, the second electrode (cathode) 516 is electrically connected to the FPC 508 which is the external input terminal.

Although the cross-sectional view of FIG. 5B illustrates only one light-emitting element 517, a plurality of light-emitting elements are arranged in matrix in the pixel portion 502. Light-emitting elements which provide three kinds of light emission (R, G, and B) are selectively formed in the pixel portion 502, whereby a light-emitting device capable of full color display can be formed. Alternatively, a light-emitting device which is capable of full color display may be manufactured by a combination with color filters.

Further, the sealing substrate 506 is attached to the element substrate 501 with the sealant 505, whereby the light-emitting element 517 is provided in a space 518 surrounded by the element substrate 501, the sealing substrate 506, and the sealant 505. The space 518 may be filled with an inert gas (such as nitrogen or argon), or the sealant 505.

An epoxy-based resin is preferably used for the sealant 505. It is preferable that such a material do not transmit moisture or oxygen as much as possible. As the sealing substrate 506, a glass substrate, a quartz substrate, or a plastic substrate formed of fiberglass reinforced plastic (FRP), polyvinyl fluoride (PVF), polyester, acrylic, or the like can be used.

As described above, an active matrix light-emitting device can be obtained.

Note that the structure described in this embodiment can be used in combination with any of the structures described in the other embodiments, as appropriate.

### Embodiment 5

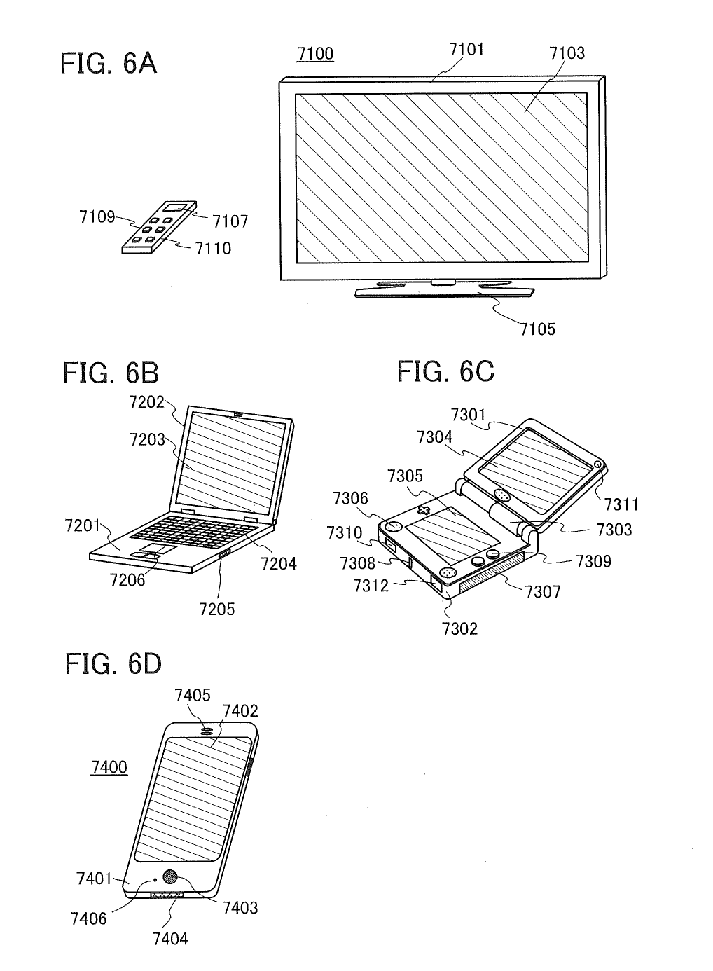

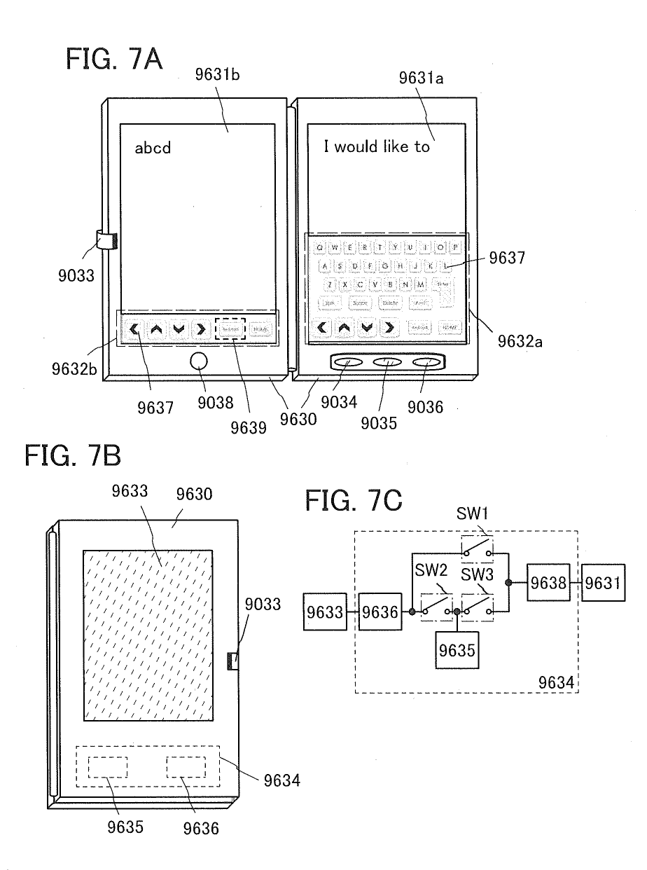

In this embodiment, examples of a variety of electronic devices which are completed using a light-emitting device, which is fabricated using a light-emitting element of an embodiment of the present invention, are described with reference to FIGS. 6A to 6D and FIGS. 7A to 7C.

Examples of the electronic devices to which the light-emitting device is applied are a television device (also referred to as a television or a television receiver), a monitor of a computer or the like, a camera such as a digital camera or a digital video camera, a digital photo frame, a mobile phone (also referred to as cellular phone or cellular phone device), a portable game machine, a portable information terminal, an audio reproducing device, and a large-sized game machine such as a pachinko machine. Specific examples of these electronic devices are illustrated in FIGS. 6A to 6D.

FIG. 6A illustrates an example of a television set. In a television set 7100, a display portion 7103 is incorporated in a housing 7101. Images can be displayed on the display portion 7103, and the light-emitting device can be used for the display portion 7103. In addition, here, the housing 7101 is supported by a stand 7105.

Operation of the television set 7100 can be performed with an operation switch of the housing 7101 or a separate remote controller 7110. With operation keys 7109 of the remote controller 7110, channels and volume can be controlled and images displayed on the display portion 7103 can be controlled. Furthermore, the remote controller 7110 may be provided with a display portion 7107 for displaying data output from the remote controller 7110.

Note that the television set 7100 is provided with a receiver, a modem, and the like. With the receiver, a general television broadcast can be received. Furthermore, when the television set 7100 is connected to a communication network by wired or wireless connection via the modem, one-way (from a transmitter to a receiver) or two-way (between a transmitter and a receiver, between receivers, or the like) data communication can be performed.

FIG. 6B illustrates a computer having a main body 7201, a housing 7202, a display portion 7203, a keyboard 7204, an external connection port 7205, a pointing device 7206, and the like. Note that this computer is manufactured using the light-emitting device for the display portion 7203.

FIG. 6C illustrates a portable game machine having two housings, a housing 7301 and a housing 7302, which are connected with a joint portion 7303 so that the portable game machine can be opened or folded. A display portion 7304 is incorporated in the housing 7301, and a display portion 7305 is incorporated in the housing 7302. In addition, the portable game machine illustrated in FIG. 6C includes a speaker portion 7306, a recording medium insertion portion 7307, an LED lamp 7308, input means (an operation key 7309, a connection terminal 7310, a sensor 7311 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), and a microphone 7312), and the like. Needless to say, the structure of the portable game machine is not limited to the above as long as the light-emitting device is used for at least one of the display portion 7304 and the display portion 7305, and may include other accessories as appropriate. The portable game machine illustrated in FIG. 6C has a function of reading out a program or data stored in a storage medium to display it on the display portion, and a function of sharing information with another portable game machine by wireless communication. The portable game machine illustrated in FIG. 6C can have a variety of functions without limitation to the above.

FIG. 6D illustrates an example of a mobile phone. A mobile phone 7400 is provided with a display portion 7402 incorporated in a housing 7401, an operation button 7403, an external connection port 7404, a speaker 7405, a microphone 7406, and the like. Note that the mobile phone 7400 is manufactured using the light-emitting device for the display portion 7402.

When the display portion 7402 of the mobile phone 7400 illustrated in FIG. 6D is touched with a finger or the like, data can be input to the mobile phone 7400. Further, operations such as making a call and composing an e-mail can be performed by touching the display portion 7402 with a finger or the like.

There are mainly three screen modes of the display portion 7402. The first mode is a display mode mainly for displaying images. The second mode is an input mode mainly for inputting data such as text. The third mode is a display-and-input mode in which two modes of the display mode and the input mode are combined.

For example, in the case of making a call or composing an e-mail, a text input mode mainly for inputting text is selected for the display portion 7402 so that text displayed on the screen can be input. In this case, it is preferable to display a keyboard or number buttons on almost the entire screen of the display portion 7402.

When a detection device including a sensor for detecting inclination, such as a gyroscope or an acceleration sensor, is provided inside the mobile phone 7400, display on the screen of the display portion 7402 can be automatically switched by determining the orientation of the mobile phone 7400 (whether the mobile phone is placed horizontally or vertically for a landscape mode or a portrait mode).

The screen modes are switched by touching the display portion 7402 or operating the operation button 7403 of the housing 7401. The screen modes can also be switched depending on the kind of image displayed on the display portion 7402. For example, when a signal of an image displayed on the display portion is a signal of moving image data, the screen mode is switched to the display mode. When the signal is a signal of text data, the screen mode is switched to the input mode.

Moreover, in the input mode, when input by touching the display portion 7402 is not performed for a certain period while a signal detected by an optical sensor in the display portion 7402 is detected, the screen mode may be controlled so as to be switched from the input mode to the display mode.

The display portion 7402 may function as an image sensor. For example, an image of a palm print, a fingerprint, or the like is taken when the display portion 7402 is touched with the palm or the finger, whereby personal authentication can be performed. Further, by providing a backlight or a sensing light source which emits near-infrared light in the display portion, an image of a finger vein, a palm vein, or the like can be taken.

FIGS. 7A and 7B illustrate a tablet terminal that can be folded. In FIG. 7A, the tablet terminal is opened, and includes a housing 9630, a display portion 9631a, a display portion 9631b, a display-mode switching button 9034, a power button 9035, a power-saving-mode switching button 9036, a clip 9033, and an operation button 9038. The tablet terminal is manufactured using the light-emitting device for one or both of the display portion 9631a and the display portion 9631b.

A touch panel area 9632a can be provided in a part of the display portion 9631a, in which area, data can be input by touching displayed operation keys 9637. Note that half of the display portion 9631a has only a display function and the other half has a touch panel function. However, an embodiment of the present invention is not limited to this structure, and the whole display portion 9631a may have a touch panel function. For example, a keyboard can be displayed on the whole display portion 9631a to be used as a touch panel, and the display portion 9631b can be used as a display screen.

A touch panel area 9632b can be provided in part of the display portion 9631b like in the display portion 9631a. When a keyboard display switching button 9639 displayed on the touch panel is touched with a finger, a stylus, or the like, a keyboard can be displayed on the display portion 9631b.

The touch panel area 9632a and the touch panel area 9632b can be controlled by touch input at the same time.

The display-mode switching button 9034 allows switching between a landscape mode and a portrait mode, color display and black-and-white display, and the like. The power-saving-mode switching button 9036 allows optimizing the display luminance in accordance with the amount of external light in use which is detected by an optical sensor incorporated in the tablet terminal. In addition to the optical sensor, another detecting device such as a sensor for detecting inclination, like a gyroscope or an acceleration sensor, may be incorporated in the tablet terminal.

Although the display portion 9631a and the display portion 9631b have the same display area in FIG. 7A, an embodiment of the present invention is not limited to this example. The display portion 9631a and the display portion 9631b may have different areas or different display quality. For example, higher definition images may be displayed on one of the display portions 9631a and 9631b.

FIG. 7B illustrates the tablet terminal folded, which includes the housing 9630, a solar battery 9633, a charge and discharge control circuit 9634, a battery 9635, and a DCDC converter 9636. Note that FIG. 7B shows an example in which the charge and discharge control circuit 9634 includes the battery 9635 and the DCDC converter 9636.

Since the tablet terminal can be folded, the housing 9630 can be closed when not in use. Thus, the display portions 9631a and 9631b can be protected, which makes it possible to provide a tablet terminal with high durability and improved reliability for long-term use.

The tablet terminal illustrated in FIGS. 7A and 7B can have other functions such as a function of displaying various kinds of data (e.g., a still image, a moving image, and a text image), a function of displaying a calendar, a date, the time, or the like on the display portion, a touch-input function of operating or editing the data displayed on the display portion by touch input, and a function of controlling processing by various kinds of software (programs).

The solar battery 9633, which is attached on the surface of the tablet terminal, supplies electric power to a touch panel, a display portion, an image signal processor, and the like. Note that the solar battery 9633 can be provided on one or both surfaces of the housing 9630 and the battery 9635 can be charged efficiently. The use of a lithium ion battery as the battery 9635 is advantageous in downsizing or the like.

The structure and operation of the charge and discharge control circuit 9634 illustrated in FIG. 7B are described with reference to a block diagram of FIG. 7C. FIG. 7C illustrates the solar battery 9633, the battery 9635, the DCDC converter 9636, a converter 9638, switches SW1 to SW3, and the display portion 9631. The battery 9635, the DCDC converter 9636, the converter 9638, and the switches SW1 to SW3 correspond to the charge and discharge control circuit 9634 in FIG. 7B.

First, description is made on an example of the operation in the case where power is generated by the solar battery 9633 using external light. The voltage of power generated by the solar battery is raised or lowered by the DCDC converter 9636 so that a voltage for charging the battery 9635 is obtained. When the display portion 9631 is operated with the power from the solar battery 9633, the switch SW1 is turned on and the voltage of the power is raised or lowered by the converter 9638 to a voltage needed for operating the display portion 9631. When display is not performed on the display portion 9631, the switch SW1 is turned off and the switch SW2 is turned on so that the battery 9635 can be charged.

Although the solar battery 9633 is shown as an example of a power generation means, there is no particular limitation on the power generation means and the battery 9635 may be charged with another means such as a piezoelectric element or a thermoelectric conversion element (Peltier element). For example, the battery 9635 may be charged with a non-contact power transmission module that transmits and receives power wirelessly (without contact) to charge the battery or with a combination of other charging means.

It is needless to say that an embodiment of the present invention is not limited to the electronic device illustrated in FIGS. 7A to 7C as long as the display portion described in the above embodiment is included.

As described above, the electronic devices can be obtained by the use of the light-emitting device according to an embodiment of the present invention. The light-emitting device has a remarkably wide application range, and can be applied to electronic devices in a variety of fields.

Note that the structure described in this embodiment can be used in combination with any of the structures described in the other embodiments, as appropriate.

### Embodiment 6

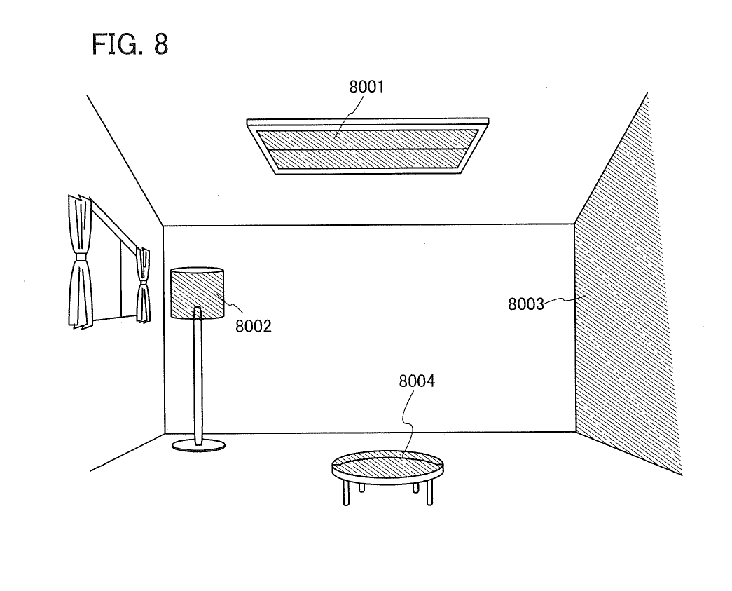

In this embodiment, examples of a lighting device to which a light-emitting device including a light-emitting element of an embodiment of the present invention is applied, are described with reference to FIG. 8.

FIG. 8 illustrates an example in which the light-emitting device is used as an indoor lighting device 8001. Since the light-emitting device can have a larger area, it can be used for a lighting device having a large area. In addition, a lighting device 8002 in which a light-emitting region has a curved surface can also be obtained with the use of a housing with a curved surface. A light-emitting element included in the light-emitting device described in this embodiment is in a thin film form, which allows the housing to be designed more freely. Therefore, the lighting device can be elaborately designed in a variety of ways. Further, a wall of the room may be provided with a large-sized lighting device 8003.

Moreover, when the light-emitting device is used for a table by being used as a surface of a table, a lighting device 8004 which has a function as a table can be obtained. When the light-emitting device is used as part of other furniture, a lighting device which has a function as the furniture can be obtained.

In this manner, a variety of lighting devices to which the light-emitting device is applied can be obtained. Note that such lighting devices are also embodiments of the present invention.

Note that the structure described in this embodiment can be used in combination with any of the structures described in the other embodiments, as appropriate.

### Example 1

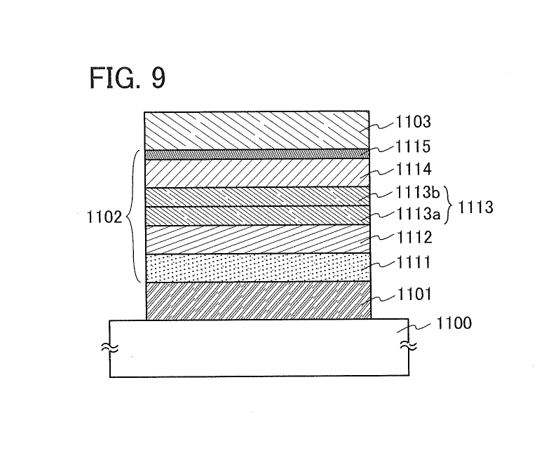

In this example, a light-emitting element 1 and a light-emitting element 2 which are embodiments of the present invention are described with reference to FIG. 9. Chemical formulae of materials used in this example are shown below.

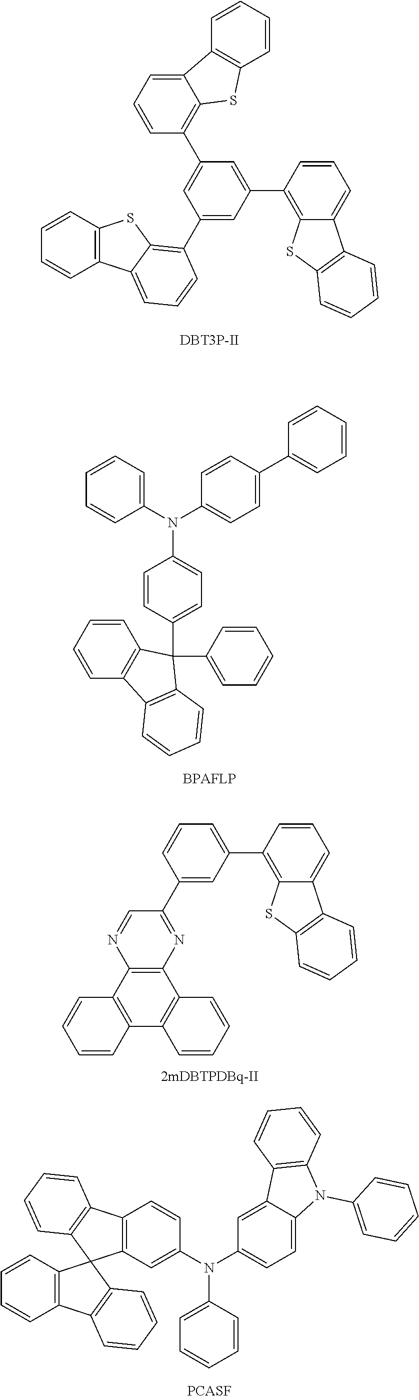

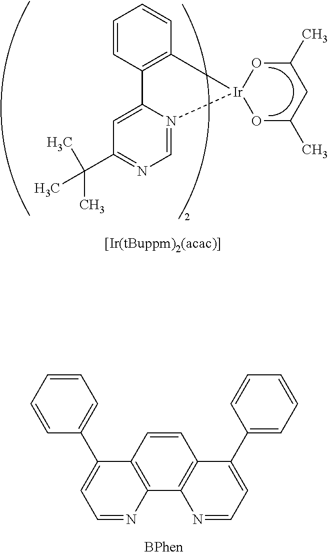

### (Fabrication of Light-Emitting Element 1 and Light-Emitting Element 2)

First, a film of indium oxide-tin oxide containing silicon oxide (ITSO) was formed over a glass substrate 1100 by a sputtering method, so that a first electrode 1101 functioning as an anode was formed. The thickness was 110 nm and the electrode area was 2 mm×2 mm.

Next, as pretreatment for forming the light-emitting element over the substrate 1100, the surface of the substrate was washed with water, baked at 200° C. for 1 hour, and subjected to UV ozone treatment for 370 seconds.

After that, the substrate 1100 was transferred into a vacuum evaporation apparatus in which the pressure had been reduced to approximately 10⁻⁴ Pa, and subjected to vacuum baking at 170° C. for 30 minutes in a heating chamber of the vacuum evaporation apparatus, and then the substrate 1100 was cooled down for about 30 minutes.

Then, the substrate 1100 over which the first electrode 1101 was formed was fixed to a substrate holder provided in the vacuum evaporation apparatus so that the surface provided with the first electrode 1101 faced downward. In this example, a case will be described in which a hole-injection layer 1111, a hole-transport layer 1112, a light-emitting layer 1113, an electron-transport layer 1114, and an electron-injection layer 1115 which are included in an EL layer 1102 are sequentially formed by a vacuum evaporation method.

After reducing the pressure in the vacuum evaporation apparatus to 10⁻⁴ Pa, 1,3,5-tri(dibenzothiophen-4-yl)benzene (abbreviation: DBT3P-II) and molybdenum(VI) oxide were co-evaporated with a mass ratio of DBT3P-II (abbreviation) to molybdenum oxide being 4:2, whereby the hole-injection layer 1111 was formed over the first electrode 1101. The thickness was 20 nm. Note that a co-evaporation method is an evaporation method in which a plurality of different substances is concurrently vaporized from respective different evaporation sources.

Then, for the light-emitting element 1, 4-phenyl-4′-(9-phenylfluoren-9-yl)triphenylamine (abbreviation: BPAFLP) was evaporated to a thickness of 20 nm, so that the hole-transport layer 1112 was formed. For the light-emitting element 2, PCASF (abbreviation) was evaporated to a thickness of 20 nm, so that the hole-transport layer 1112 was formed.

Next, the light-emitting layer 1113 was formed over the hole-transport layer 1112. For the light-emitting element 1, 2-[3-(dibenzothiophen-4-yl)phenyl]dibenzo[f,h]quinoxaline (abbreviation: 2mDBTPDBq-II) and 2-[N-(9-phenylcarbazol-3-yl)-N-phenylamino]-spiro-9,9′-bifluorene (abbreviation: PCASF) were co-evaporated with a mass ratio of 2mDBTPDBq-II (abbreviation) to PCASF (abbreviation) being 0.8:0.2, so that the light-emitting layer 1113 with a thickness of 40 nm was formed. For the light-emitting element 2, 2mDBTPDBq-II (abbreviation), PCASF (abbreviation), and (acetylacetonato)bis(6-tert-butyl-4-phenylpyrimidinato)iridium(III) (abbreviation: [Ir(tBuppm)₂(acac)] were co-evaporated to a thickness of 20 nm with a mass ratio of 2mDBTPDBq-II (abbreviation) to PCASF (abbreviation) and [Ir(tBuppm)₂(acac)] (abbreviation) being 0.7:0.3:0.05, and then further co-evaporated to a thickness of 20 nm with a mass ratio of 2mDBTPDBq-II (abbreviation) to PCASF (abbreviation) and [Ir(tBuppm)₂(acac)] (abbreviation) being 0.8:0.2:0.05; thus, the light-emitting layer 1113 was formed.

Then, 2mDBTPDBq-II (abbreviation) was evaporated to a thickness of 5 nm over the light-emitting layer 1113 and bathophenanthroline (abbreviation: Bphen) was evaporated to a thickness of 15 nm, whereby the electron-transport layer 1114 having a stacked structure was formed. Furthermore, lithium fluoride was evaporated to a thickness of 1 nm over the electron-transport layer 1114, whereby the electron-injection layer 1115 was formed.

Finally, aluminum was evaporated to a thickness of 200 nm over the electron-injection layer 1115 to form a second electrode 1103 serving as a cathode; thus, the light-emitting element 1 and the light-emitting element 2 were obtained. Note that, in the above evaporation process, evaporation was all performed by a resistance heating method.

In the above-described manner, the light-emitting element 1 and the light-emitting element 2 were obtained. Table 1 shows element structures of the light-emitting element 1 and the light-emitting element 2.

TABLE 1

| | First | Hole-injection | Hole-transport | Light-emitting | | Electron-transport | | Electron-injection | Second |
|---|---|---|---|---|---|---|---|---|---|
| | electrode | layer | layer | layer | | layer | | layer | electrode |
| Light-emitting | ITSO | DBT3P-II:MoOx | BPAFLP | * | | 2mDBTPDBq-II | Bphen | LiF | Al |
| element 1 | (110 nm) | (4:2 20 nm) | (20 nm) | | | (5 nm) | (15 nm) | (1 nm) | (200 nm) |
| Light-emitting | ITSO | DBT3P-II:MoOx | PCASF | ** | *** | 2mDBTPDBq-II | Bphen | LiF | Al |
| element 2 | (110 nm) | (4:2 20 nm) | (20 nm) | | | (5 nm) | (15 nm) | (1 nm) | (200 nm) |

* 2mDBTPDBq-II:PCASF (0.8:0.2 40 nm)
** 2mDBTPDBq-II:PCASF:[Ir(tBuppm)₂(acac)] (0.7:0.3:0.05 20 nm)
*** 2mDBTPDBq-II:PCASF:[Ir(tBuppm)₂(acac)] (0.8:0.2:0.05 20 nm)

Further, the fabricated light-emitting elements 1 and 2 were sealed in a glove box containing a nitrogen atmosphere so as not to be exposed to the air (specifically, a sealant was applied onto outer edges of the elements and heat treatment was performed at 80° C. for 1 hour at the time of sealing).

### (Operation Characteristics of Light-Emitting Element 1 and Light-Emitting Element 2)

Operation characteristics of the fabricated light-emitting elements 1 and 2 were measured. Note that the measurement was carried out at room temperature (in an atmosphere kept at 25° C.).

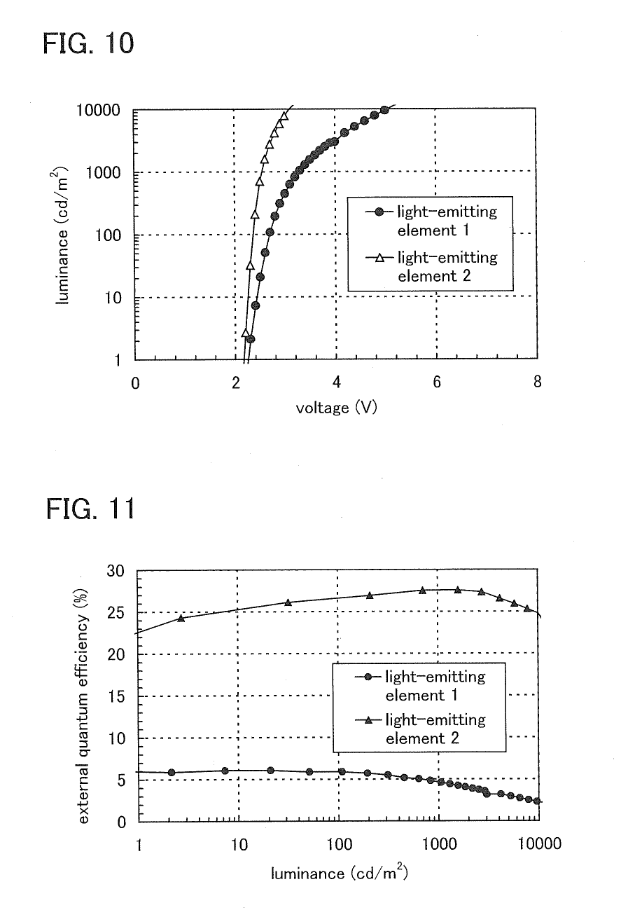

FIG. 10 and FIG. 11 show voltage-luminance characteristics and luminance-external quantum efficiency characteristics, respectively, of the light-emitting elements 1 and 2.

According to FIG. 11, the light-emitting element 1 which is one embodiment of the present invention has a maximum external quantum efficiency of about 6.1%. An external quantum efficiency exceeding the theoretical external quantum efficiency (5%) was obtained because the theoretical generation probability of S1 (25%) is increased by the formation of an exciplex in the light-emitting layer. The light-emitting element of one embodiment of the present invention is characterized by having a relatively high emission efficiency by contributing part of triplet excited energy to light emission, without the need of using a high-cost Ir complex as a light-emitting material.

Further in the light-emitting element 2 including a light-emitting substance that converts triplet excited energy into light emission in the light-emitting layer, the maximum external quantum efficiency is as high as about 28%. The external quantum efficiency in this light-emitting element is extremely high because the transfer efficiency of energy from T1 of the exciplex to the light-emitting substance that converts triplet excited energy into light emission is increased by the formation of an exciplex in the light-emitting layer.

Table 2 shows initial values of main characteristics of the light-emitting element 1 and the light-emitting element 2 at a luminance of about 1000 cd/m².

TABLE 2

| | | | | | | | | External |
|---|---|---|---|---|---|---|---|---|
| | | | Current | | | Current | Power | quantum |
| | Voltage | Current | density | Chromaticity | Luminance | efficiency | efficiency | efficiency |
| | (V) | (mA) | (mA/cm²) | (x, y) | (cd/m²) | (cd/A) | (lm/W) | (%) |
| Light-emitting | 3.3 | 0.28 | 7 | (0.44, 0.54) | 1100 | 15 | 14 | 4.6 |
| element 1 | | | | | | | | |
| Light-emitting | 2.5 | 0.026 | 0.66 | (0.40, 0.59) | 710 | 110 | 130 | 25 |
| element 2 | | | | | | | | |

The results in Table 2 also show that the light-emitting element 1 and the light-emitting element 2 fabricated in this example have high luminance and high current efficiency.

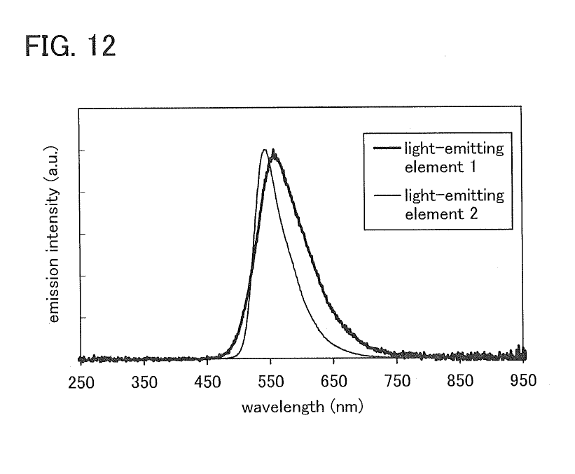

FIG. 12 shows emission spectra of the light-emitting element 1 and the light-emitting element 2 which were obtained by application of a current of 0.1 mA. As shown in FIG. 12, the light-emitting element 1 has a peak of emission spectrum at around 561 nm; this peak derives from the emission of the exciplex formed by 2mDBTPDBq-II (abbreviation) and PCASF (abbreviation) in the light-emitting layer 1113. The light-emitting element 2 has a peak of emission spectrum at around 546 nm; this peak derives from the emission of [Ir(tBuppm)₂(acac)] (abbreviation) included in the light-emitting layer 1113.

Thus, the light-emitting element of one embodiment of the present invention in which the exciplex can be formed in the light-emitting layer was found to have high emission efficiency.

In the light-emitting element 2, the emission peak wavelength of the exciplex formed by 2mDBTPDBq-II (abbreviation) and PCASF (abbreviation) used in the light-emitting layer (see the light-emitting element 1) is longer than the emission peak wavelength of [Ir(tBuppm)₂(acac)] that is a phosphorescent light-emitting substance; however, the difference therebetween is within the range of 0.1 eV. With this structure, a light emission start voltage that is lower than the conventional one as well as high emission efficiency can be achieved. As a result, the light-emitting element 2 can have as high power efficiency as 140 lm/W at a maximum (at 32 cd/m²).

Since the light-emitting element 2 uses PCASF (abbreviation) in not only the light-emitting layer but also the hole-transport layer, the hole-injection barrier between the hole-transport layer and the light-emitting layer is reduced. Accordingly, the operation voltage in a practical luminance region (e.g., about 1,000 cd/m²) is as extremely low as 2.5 V. Accordingly, the power efficiency in the practical luminance region (e.g., about 1,000 cd/m²) is about 130 lm/W, which is little decreased from the maximum value (140 lm/W) (see Table 2). By using a material similar to the second organic compound (particularly preferably, the same material as the second organic compound) in the hole-transport layer as well as the light-emitting layer, a light-emitting element having a small decrease in power efficiency due to loss of voltage even in the case of emitting light with high luminance can be obtained.

### Example 2

In this example, a light-emitting element 3 and a light-emitting element 4 which are embodiments of the present invention are described. Note that FIG. 9, which is used for the description of the light-emitting elements 1 and 2 in Example 1, is used for describing the light-emitting elements 3 and 4 in this example. Chemical formulae of materials used in this example are shown below.

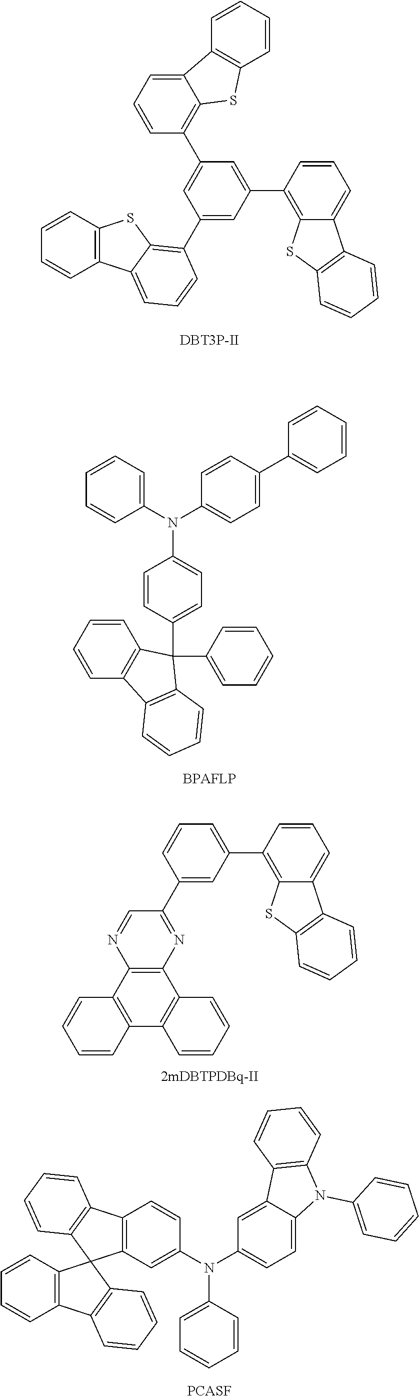

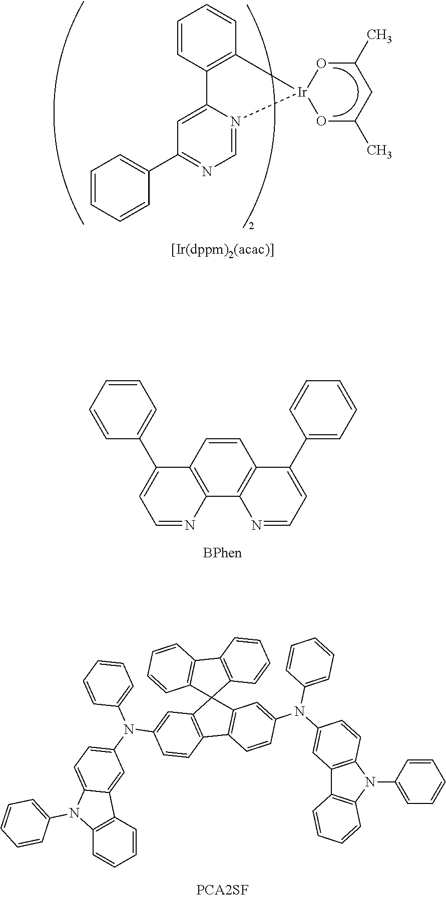

### (Fabrication of Light-Emitting Element 3 and Light-Emitting Element 4)

First, a film of indium tin oxide containing silicon oxide (ITSO) was formed over a glass substrate 1100 by a sputtering method, so that a first electrode 1101 functioning as an anode was formed. The thickness was 110 nm and the electrode area was 2 mm×2 mm.

Next, as pretreatment for forming the light-emitting element over the substrate 1100, the surface of the substrate was washed with water, baked at 200° C. for 1 hour, and subjected to UV ozone treatment for 370 seconds.

After that, the substrate 1100 was transferred into a vacuum evaporation apparatus in which the pressure had been reduced to approximately 10⁻⁴ Pa, and subjected to vacuum baking at 170° C. for 30 minutes in a heating chamber of the vacuum evaporation apparatus, and then the substrate 1100 was cooled down for about 30 minutes.

Then, the substrate 1100 over which the first electrode 1101 was formed was fixed to a substrate holder provided in the vacuum evaporation apparatus so that the surface provided with the first electrode 1101 faced downward. In this example, a case will be described in which a hole-injection layer 1111, a hole-transport layer 1112, a light-emitting layer 1113, an electron-transport layer 1114, and an electron-injection layer 1115 which are included in an EL layer 1102 are sequentially formed by a vacuum evaporation method.

After reducing the pressure in the vacuum evaporation apparatus to 10⁻⁴ Pa, 1,3,5-tri(dibenzothiophen-4-yl)benzene (abbreviation: DBT3P-II) and molybdenum(VI) oxide were co-evaporated with a mass ratio of DBT3P-II (abbreviation) to molybdenum oxide being 4:2, whereby the hole-injection layer 1111 was formed over the first electrode 1101. The thickness was 20 nm. Note that a co-evaporation method is an evaporation method in which a plurality of different substances is concurrently vaporized from respective different evaporation sources.

Then, for the light-emitting element 3, 4-phenyl-4′-(9-phenylfluoren-9-yl)triphenylamine (abbreviation: BPAFLP) was evaporated to a thickness of 20 nm, so that the hole-transport layer 1112 was formed. For the light-emitting element 4, PCASF (abbreviation) was evaporated to a thickness of 20 nm, so that the hole-transport layer 1112 was formed.

Next, the light-emitting layer 1113 was formed over the hole-transport layer 1112. For the light-emitting element 3, 2-[3-(dibenzothiophen-4-yl)phenyl]dibenzo[f,h]quinoxaline (abbreviation: 2mDBTPDBq-II) and N,N-bis(9-phenyl-9H-carbazol-3-yl)-N,N′-diphenyl-spiro-9,9′-bifluorene-2,7-diamine (abbreviation: PCA2SF) were co-evaporated with a mass ratio of 2mDBTPDBq-II (abbreviation) to PCA2SF (abbreviation) being 0.8:0.2. The thickness of the light-emitting layer 1113 was 40 nm. For the light-emitting element 4, 2mDBTPDBq-II (abbreviation), PCA2SF (abbreviation), and (acetylacetonato)bis(4,6-diphenylpyrimidinato)iridium(III) (abbreviation: [Ir(dppm)₂(acac)]) were co-evaporated to a thickness of 20 nm with a mass ratio of 2mDBTPDBq-II (abbreviation) to PCA2SF (abbreviation) and [Ir(dppm)₂(acac)](abbreviation) being 0.7:0.3:0.05, and then further co-evaporated to a thickness of 20 nm with a mass ratio of 2mDBTPDBq-II (abbreviation) to PCA2SF (abbreviation) and [Ir(dppm)₂(acac)] (abbreviation) being 0.8:0.2:0.05; thus, the light-emitting layer 1113 was formed.

Then, 2mDBTPDBq-II (abbreviation) was evaporated to a thickness of 20 nm over the light-emitting layer 1113 and bathophenanthroline (abbreviation: Bphen) was evaporated to a thickness of 20 nm, whereby the electron-transport layer 1114 having a stacked structure was formed. Furthermore, lithium fluoride was evaporated to a thickness of 1 nm over the electron-transport layer 1114, whereby the electron-injection layer 1115 was formed.

Finally, aluminum was evaporated to a thickness of 200 nm over the electron-injection layer 1115 to form a second electrode 1103 serving as a cathode; thus, the light-emitting element 3 and the light-emitting element 4 were obtained. Note that, in the above evaporation process, evaporation was all performed by a resistance heating method.

In the above-described manner, the light-emitting element 3 and the light-emitting element 4 were obtained. Table 3 shows element structures of the light-emitting element 3 and the light-emitting element 4.

TABLE 3

| | First | Hole-injection | Hole-transport | Light-emitting | | Electron-transport | | Electron-injection | Second |
|---|---|---|---|---|---|---|---|---|---|
| | electrode | layer | layer | layer | | layer | | layer | electrode |
| Light-emitting | ITSO | DBT3P-II:MoOx | BPAFLP | * | | 2mDBTPDBq-II | Bphen | LiF | Al |
| element 3 | (110 nm) | (4:2 20 nm) | (20 nm) | | | (20 nm) | (20 nm) | (1 nm) | (200 nm) |
| Light-emitting | ITSO | DBT3P-II:MoOx | PCASF | ** | *** | 2mDBTPDBq-II | Bphen | LiF | Al |
| element 4 | (110 nm) | (4:2 20 nm) | (20 nm) | | | (20 nm) | (20 nm) | (1 nm) | (200 nm) |

* 2mDBTPDBq-II:PCA2SF (0.8:0.2 40 nm)
** 2mDBTPDBq-II:PCA2SF:[Ir(dppm)₂(acac)] (0.7:0.3:0.05 20 nm)
*** 2mDBTPDBq-II:PCA2SF:[Ir(dppm)₂(acac)] (0.8:0.2:0.05 20 nm)

Further, the fabricated light-emitting elements 3 and 4 were sealed in a glove box containing a nitrogen atmosphere so as not to be exposed to the air (specifically, a sealant was applied onto outer edges of the elements and heat treatment was performed at 80° C. for 1 hour at the time of sealing).

### (Operation Characteristics of Light-Emitting Element 3 and Light-Emitting Element 4)

Operation characteristics of the fabricated light-emitting elements 3 and 4 were measured. Note that the measurement was carried out at room temperature (in an atmosphere kept at 25° C.).

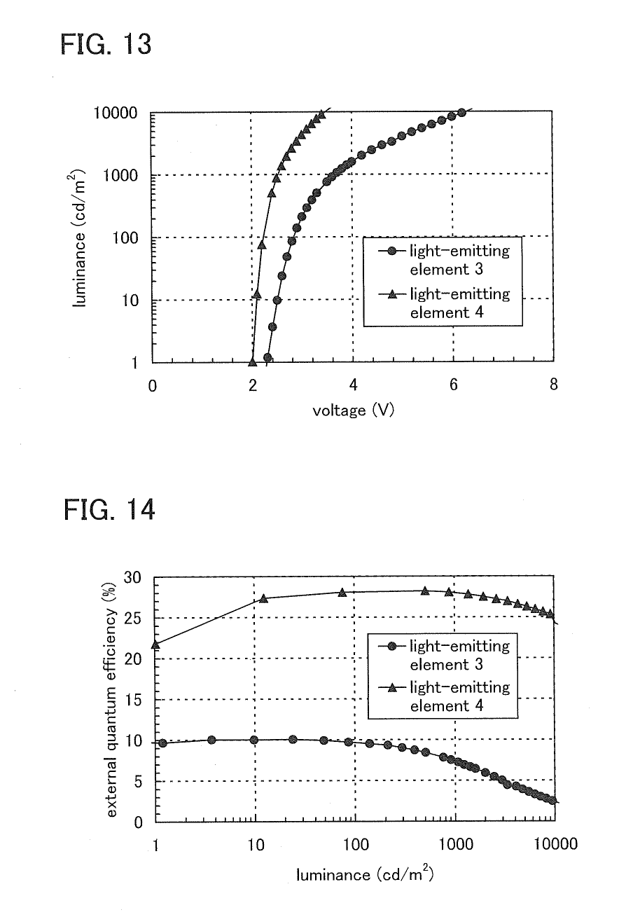

FIG. 13 and FIG. 14 show voltage-luminance characteristics and luminance-external quantum efficiency characteristics, respectively, of the light-emitting elements 3 and 4.

According to FIG. 14, the light-emitting element 3 which is one embodiment of the present invention has a maximum external quantum efficiency of about 10%. An external quantum efficiency well over the theoretical external quantum efficiency (5%) was obtained because the theoretical generation probability of S1 (25%) is increased by the formation of an exciplex in the light-emitting layer. The light-emitting element of one embodiment of the present invention is characterized by having a relatively high emission efficiency by contributing part of triplet excited energy to light emission, without the need of using a high-cost Ir complex as a light-emitting material.

Further in the light-emitting element 4 including a light-emitting substance that converts triplet excited energy into light emission in the light-emitting layer, the maximum external quantum efficiency is as high as about 28%. The external quantum efficiency in this light-emitting element is extremely high because the transfer efficiency of energy from T1 of the exciplex to the light-emitting substance that converts triplet excited energy into light emission is increased by the formation of an exciplex in the light-emitting layer.

Table 4 shows initial values of main characteristics of the light-emitting element 3 and the light-emitting element 4 at a luminance of about 1000 cd/m².

TABLE 4

| | | | | | | | | External |
|---|---|---|---|---|---|---|---|---|
| | | | Current | | | Current | Power | quantum |
| | Voltage | Current | density | Chromaticity | Luminance | efficiency | efficiency | efficiency |
| | (V) | (mA) | (mA/cm²) | (x, y) | (cd/m²) | (cd/A) | (lm/W) | (%) |
| Light-emitting | 3.7 | 0.22 | 5.5 | (0.53, 0.46) | 1100 | 19 | 16 | 7.2 |
| element 3 | | | | | | | | |
| Light-emitting | 2.5 | 0.05 | 1.2 | (0.55, 0.44) | 890 | 77 | 96 | 28 |
| element 4 | | | | | | | | |

The results in Table 4 also show that the light-emitting element 3 and the light-emitting element 4 fabricated in this example have high luminance and high current efficiency.

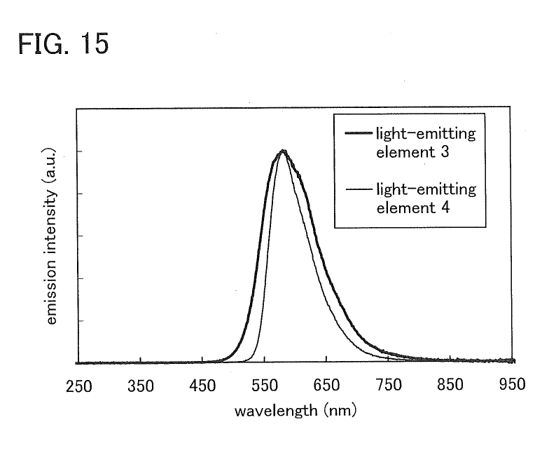

FIG. 15 shows emission spectra of the light-emitting element 3 and the light-emitting element 4 which were obtained by application of a current of 0.1 mA. As shown in FIG. 15, the light-emitting element 3 has a peak of emission spectrum at around 587 nm; this peak derives from the emission of the exciplex formed by 2mDBTPDBq-II (abbreviation) and PCA2SF (abbreviation) in the light-emitting layer 1113. The light-emitting element 4 has a peak of emission spectrum at around 587 nm; this peak derives from the emission of [Ir(dppm)₂(acac)] (abbreviation) included in the light-emitting layer 1113.

Thus, the light-emitting element of one embodiment of the present invention in which the exciplex can be formed in the light-emitting layer was found to have high emission efficiency.

In the light-emitting element 4, the emission peak wavelength of the exciplex formed by 2mDBTPDBq-II (abbreviation) and PCA2SF (abbreviation) used in the light-emitting layer (see the light-emitting element 3) is almost the same as the emission peak wavelength of [Ir(dppm)₂(acac)] (abbreviation) that is a phosphorescent light-emitting substance. With this structure, a light emission start voltage that is lower than the conventional one as well as high emission efficiency can be achieved. As a result, a high power efficiency of 110 lm/W at a maximum (at 12 cd/m²) can be obtained; the value is extremely high for an orange-light-emitting element.

Since the light-emitting element 4 uses PCASF (abbreviation), which is a compound similar to PCA2SF (abbreviation) (i.e., which has the same skeleton as PCA2SF; the skeleton is a 9-aryl-9H-carbazol-3-amine skeleton), in the hole-transport layer, the hole-injection barrier between the hole-transport layer and the light-emitting layer is reduced. Accordingly, the operation voltage in a practical luminance region (e.g., about 1,000 cd/m²) is as extremely low as 2.5 V. Accordingly, the power efficiency in the practical luminance region (e.g., about 1,000 cd/m²) is about 96 lm/W, which is little decreased from the maximum value (110 lm/W) (see Table 4). By using a material similar to the second organic compound in the hole-transport layer as well as the light-emitting layer, a light-emitting element having a small decrease in power efficiency due to loss of voltage even in the case of emitting light with high luminance can be obtained.

### Example 3

In this example, a light-emitting element 5 and a light-emitting element 6 which are embodiments of the present invention are described. Note that FIG. 9, which is used for the description of the light-emitting elements 1 and 2 in Example 1, is used for describing the light-emitting elements 5 and 6 in this example. Chemical formulae of materials used in this example are shown below.

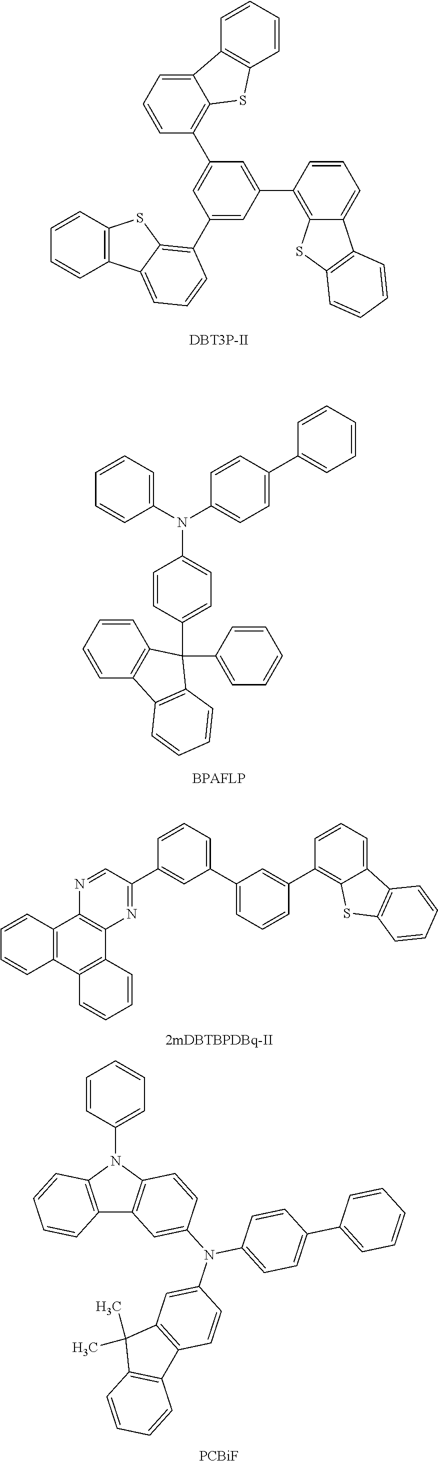

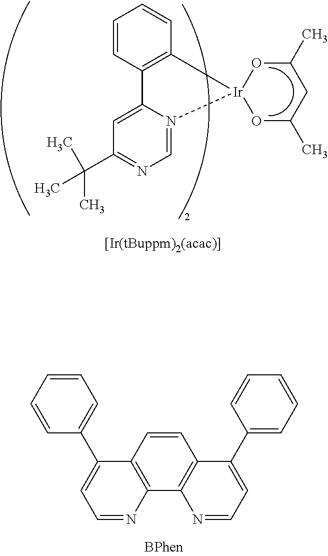

### (Fabrication of Light-Emitting Element 5 and Light-Emitting Element 6)

First, a film of indium oxide-tin oxide containing silicon oxide (ITSO) was formed over a glass substrate 1100 by a sputtering method, so that a first electrode 1101 functioning as an anode was formed. The thickness was 110 nm and the electrode area was 2 mm×2 mm.

Next, as pretreatment for forming the light-emitting element over the substrate 1100, the surface of the substrate was washed with water, baked at 200° C. for 1 hour, and subjected to UV ozone treatment for 370 seconds.

After that, the substrate 1100 was transferred into a vacuum evaporation apparatus in which the pressure had been reduced to approximately 10⁻⁴ Pa, and subjected to vacuum baking at 170° C. for 30 minutes in a heating chamber of the vacuum evaporation apparatus, and then the substrate 1100 was cooled down for about 30 minutes.

Then, the substrate 1100 over which the first electrode 1101 was formed was fixed to a substrate holder provided in the vacuum evaporation apparatus so that the surface provided with the first electrode 1101 faced downward. In this example, a case will be described in which a hole-injection layer 1111, a hole-transport layer 1112, a light-emitting layer 1113, an electron-transport layer 1114, and an electron-injection layer 1115 which are included in an EL layer 1102 are sequentially formed by a vacuum evaporation method.

After reducing the pressure in the vacuum evaporation apparatus to 10⁻⁴ Pa, 1,3,5-tri(dibenzothiophen-4-yl)benzene (abbreviation: DBT3P-II) and molybdenum(VI) oxide were co-evaporated with a mass ratio of DBT3P-II (abbreviation) to molybdenum oxide being 4:2, whereby the hole-injection layer 1111 was formed over the first electrode 1101. The thickness was 20 nm. Note that a co-evaporation method is an evaporation method in which a plurality of different substances is concurrently vaporized from respective different evaporation sources.

Then, 4-phenyl-4′-(9-phenylfluoren-9-yl)triphenylamine (abbreviation: BPAFLP) was evaporated to a thickness of 20 nm, so that the hole-transport layer 1112 was formed.

Next, the light-emitting layer 1113 was formed over the hole-transport layer 1112. For the light-emitting element 5, 2-[3′-(dibenzothiophen-4-yl)biphenyl-3-yl]dibenzo[f,h]quinoxaline (abbreviation: 2mDBTBPDBq-II) and N-(4-biphenyl)-N-(9,9-dimethyl-9H-fluoren-2-yl)-9-phenyl-9H-carbazol-3-amine (abbreviation: PCBiF) were co-evaporated with a mass ratio of 2mDBTBPDBq-II (abbreviation) to PCBiF (abbreviation) being 0.8:0.2, so that the light-emitting layer 1113 with a thickness of 40 nm was formed. For the light-emitting element 6, 2mDBTBPDBq-II (abbreviation), PCBiF (abbreviation), and (acetylacetonato)bis(6-tert-butyl-4-phenylpyrimidinato)iridium(III) (abbreviation: [Ir(tBuppm)₂(acac)] were co-evaporated to a thickness of 20 nm with a mass ratio of 2mDBTBPDBq-II (abbreviation) to PCBiF (abbreviation) and [Ir(tBuppm)₂(acac)](abbreviation) being 0.7:0.3:0.05, and then further co-evaporated to a thickness of 20 nm with a mass ratio of 2mDBTBPDBq-II (abbreviation) to PCBiF (abbreviation) and [Ir(tBuppm)₂(acac)] (abbreviation) being 0.8:0.2:0.05; thus, the light-emitting layer 1113 was formed.

Then, 2mDBTBPDBq-II (abbreviation) was evaporated to a thickness of 10 nm over the light-emitting layer 1113 and bathophenanthroline (abbreviation: Bphen) was evaporated to a thickness of 15 nm, whereby the electron-transport layer 1114 having a stacked structure was formed. Furthermore, lithium fluoride was evaporated to a thickness of 1 nm over the electron-transport layer 1114, whereby the electron-injection layer 1115 was formed.

Finally, aluminum was evaporated to a thickness of 200 nm over the electron-injection layer 1115 to form a second electrode 1103 serving as a cathode; thus, the light-emitting element 5 and the light-emitting element 6 were obtained. Note that, in the above evaporation process, evaporation was all performed by a resistance heating method.

In the above-described manner, the light-emitting element 5 and the light-emitting element 6 were obtained. Table 5 shows element structures of the light-emitting element 5 and the light-emitting element 6.

TABLE 5

| | First | Hole-injection | Hole-transport | Light-emitting | | Electron-transport | | Electron-injection | Second |
|---|---|---|---|---|---|---|---|---|---|
| | electrode | layer | layer | layer | | layer | | layer | electrode |
| Light-emitting | ITSO | DBT3P-II:MoOx | BPAFLP | * | | 2mDBTBPDBq-II | Bphen | LiF | Al |
| element 5 | (110 nm) | (4:2 20 nm) | (20 nm) | | | (10 nm) | (15 nm) | (1 nm) | (200 nm) |
| Light-emitting | ITSO | DBT3P-II:MoOx | BPAFLP | ** | *** | 2mDBTBPDBq-II | Bphen | LiF | Al |
| element 6 | (110 nm) | (4:2 20 nm) | (20 nm) | | | (10 nm) | (15 nm) | (1 nm) | (200 nm) |

* 2mDBTBPDBq-II:PCBiF (0.8:0.2 40 nm)
** 2mDBTBPDBq-II:PCBiF:[Ir(tBuppm)₂(acac)] (0.7:0.3:0.05 20 nm)
*** 2mDBTBPDBq-II:PCBiF:[Ir(tBuppm)₂(acac)] (0.8:0.2:0.05 20 nm)

Further, the fabricated light-emitting elements 5 and 6 were sealed in a glove box containing a nitrogen atmosphere so as not to be exposed to the air (specifically, a sealant was applied onto outer edges of the elements and heat treatment was performed at 80° C. for 1 hour at the time of sealing).

### (Operation Characteristics of Light-Emitting Element 5 and Light-Emitting Element 6)

Operation characteristics of the fabricated light-emitting elements 5 and 6 were measured. Note that the measurement was carried out at room temperature (in an atmosphere kept at 25° C.).

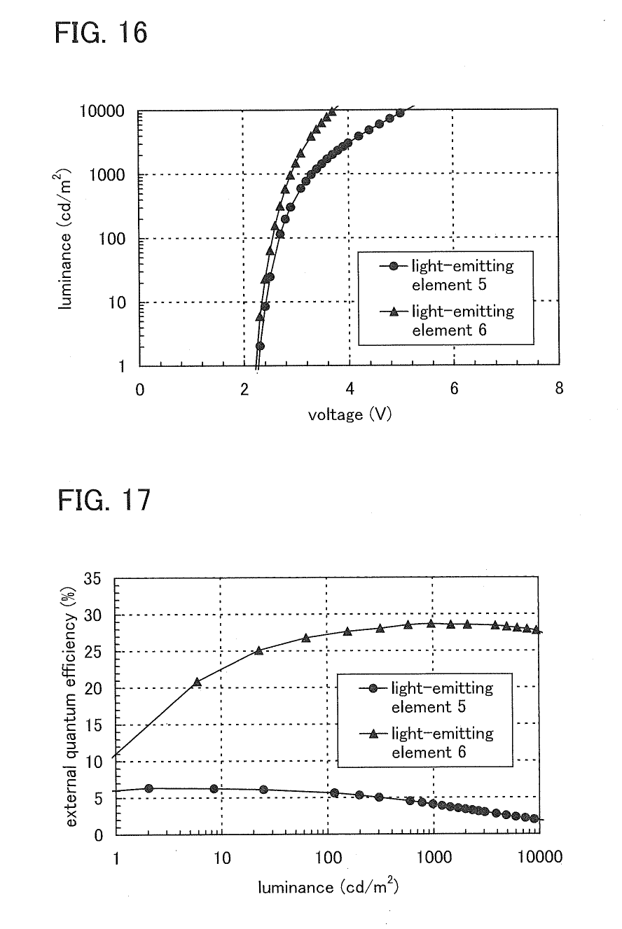

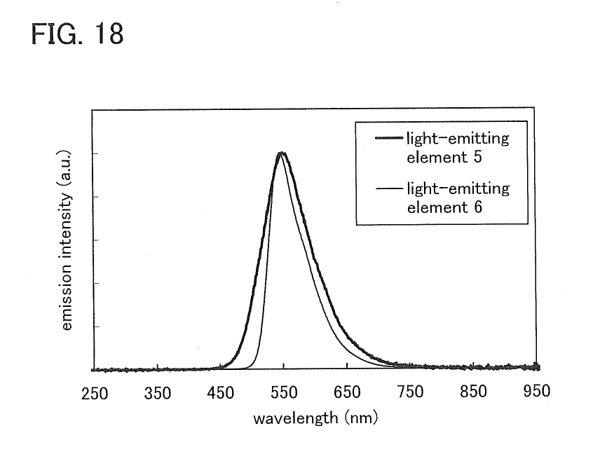

FIG. 16 and FIG. 17 show voltage-luminance characteristics and luminance-external quantum efficiency characteristics, respectively, of the light-emitting elements 5 and 6.

According to FIG. 17, the light-emitting element 5 which is one embodiment of the present invention has a maximum external quantum efficiency of about 6.4%. An external quantum efficiency exceeding the theoretical external quantum efficiency (5%) was obtained because the theoretical generation probability of S1 (25%) is increased by the formation of an exciplex in the light-emitting layer. Thus, the light-emitting element of one embodiment of the present invention is characterized by having a relatively high emission efficiency by contributing part of triplet excited energy to light emission, without the need of using a high-cost Ir complex as a light-emitting material.

Further in the light-emitting element 6 including a light-emitting substance that converts triplet excited energy into light emission in the light-emitting layer, the maximum external quantum efficiency is as high as about 29%. The external quantum efficiency in this light-emitting element is extremely high because the transfer efficiency of energy from T1 of the exciplex to the light-emitting substance that converts triplet excited energy into light emission is increased by the formation of an exciplex in the light-emitting layer.

Table 6 shows initial values of main characteristics of the light-emitting element 5 and the light-emitting element 6 at a luminance of about 1000 cd/m².

TABLE 6

| | | | | | | | | External |
|---|---|---|---|---|---|---|---|---|
| | | | Current | | | Current | Power | quantum |
| | Voltage | Current | density | Chromaticity | Luminance | efficiency | efficiency | efficiency |
| | (V) | (mA) | (mA/cm²) | (x, y) | (cd/m²) | (cd/A) | (lm/W) | (%) |
| Light-emitting | 3.3 | 0.29 | 7.1 | (0.42, 0.55) | 990 | 14 | 13 | 4.1 |
| element 5 | | | | | | | | |
| Light-emitting | 2.9 | 0.036 | 0.89 | (0.41, 0.58) | 970 | 110 | 120 | 29 |
| element 6 | | | | | | | | |

The results in Table 6 also show that the light-emitting element 5 and the light-emitting element 6 fabricated in this example have high luminance and high current efficiency.

FIG. 18 shows emission spectra of the light-emitting element 5 and the light-emitting element 6 which were obtained by application of a current of 0.1 mA. As shown in FIG. 18, the light-emitting element 5 has a peak of emission spectrum at around 550 nm; this peak derives from the emission of the exciplex formed by 2mDBTBPDBq-II (abbreviation) and PCBiF (abbreviation) in the light-emitting layer 1113. The light-emitting element 6 has a peak of emission spectrum at around 546 nm; this peak derives from the emission of [Ir(tBuppm)₂(acac)] (abbreviation) included in the light-emitting layer 1113.

Thus, the light-emitting element of one embodiment of the present invention in which the exciplex can be formed in the light-emitting layer was found to have high emission efficiency.

In the light-emitting element 6, the emission peak wavelength of the exciplex formed by 2mDBTBPDBq-II (abbreviation) and PCBiF (abbreviation) used in the light-emitting layer (see the light-emitting element 5) is longer than the emission peak wavelength of [Ir(tBuppm)₂(acac)] that is a phosphorescent light-emitting substance; however, the difference therebetween is within the range of 0.1 eV. With this structure, a light emission start voltage that is lower than the conventional one as well as high emission efficiency can be achieved. As a result, the light-emitting element 6 can have as high power efficiency as 120 lm/W (at 970 cd/m²).

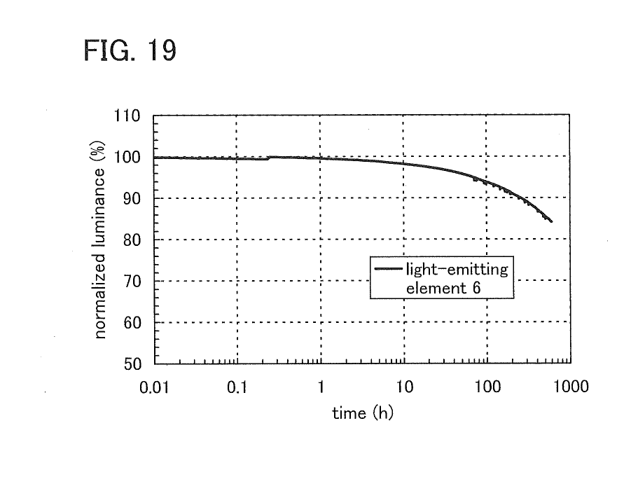

The light-emitting element 6 was subjected to a reliability test. Results of the reliability test are shown in FIG. 19. In FIG. 19, the vertical axis represents normalized luminance (%) with an initial luminance of 100%, and the horizontal axis represents driving time (h) of the element. Note that in the reliability test, the light-emitting element 6 was driven under the conditions where the initial luminance was set to 1000 cd/m² and the current density was constant. As a result, the light-emitting element 6 kept about 93% of the initial luminance after 100 hours elapsed.

Thus, the reliability test revealed high reliability of the light-emitting element 6.

### Example 4

In this example, a light-emitting element 7, a light-emitting element 8, and a light-emitting element 9 which are embodiments of the present invention are described. Note that FIG. 9, which is used for the description of the light-emitting elements 1 and 2 in Example 1, is used for describing the light-emitting elements 7, 8, and 9 in this example. Chemical formulae of materials used in this example are shown below.

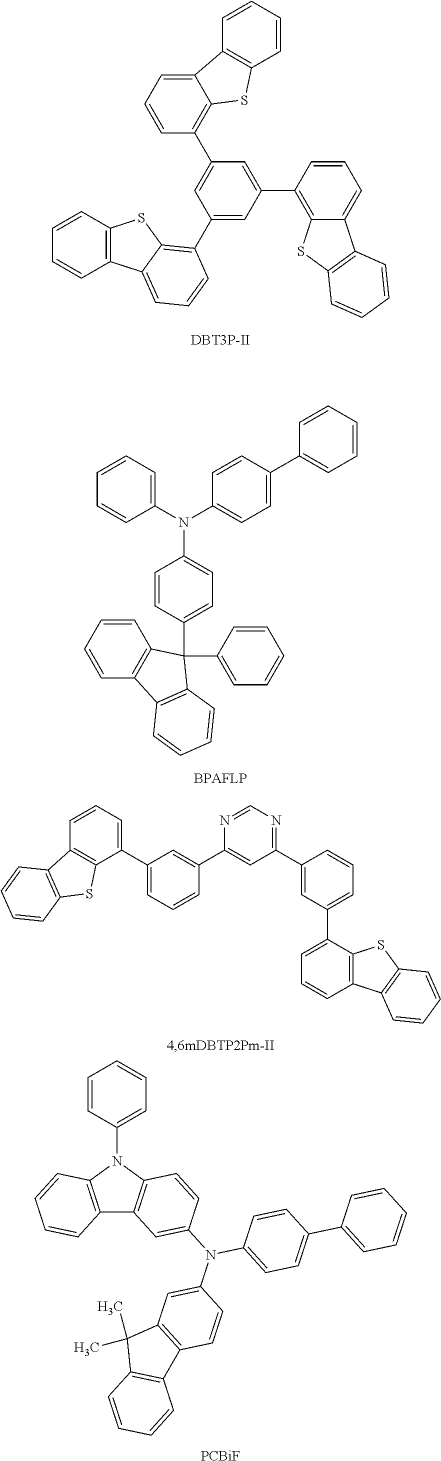

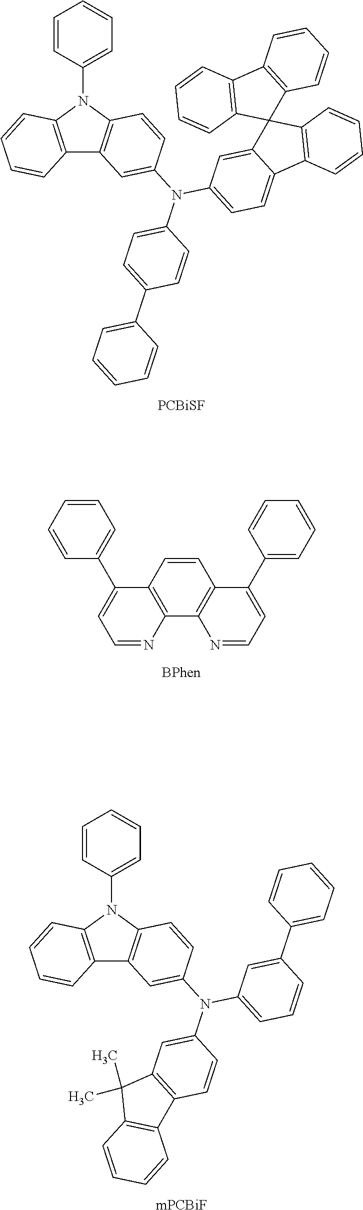

### (Fabrication of Light-Emitting Element 7, Light-Emitting Element 8, and Light-Emitting Element 9)

First, a film of indium oxide-tin oxide containing silicon oxide (ITSO) was formed over a glass substrate 1100 by a sputtering method, so that a first electrode 1101 functioning as an anode was formed. The thickness was 110 nm and the electrode area was 2 mm×2 mm.

Next, as pretreatment for forming the light-emitting element over the substrate 1100, the surface of the substrate was washed with water, baked at 200° C. for 1 hour, and subjected to UV ozone treatment for 370 seconds.

After that, the substrate 1100 was transferred into a vacuum evaporation apparatus in which the pressure had been reduced to approximately 10⁻⁴ Pa, and subjected to vacuum baking at 170° C. for 30 minutes in a heating chamber of the vacuum evaporation apparatus, and then the substrate 1100 was cooled down for about 30 minutes.

Then, the substrate 1100 over which the first electrode 1101 was formed was fixed to a substrate holder provided in the vacuum evaporation apparatus so that the surface provided with the first electrode 1101 faced downward. In this example, a case will be described in which a hole-injection layer 1111, a hole-transport layer 1112, a light-emitting layer 1113, an electron-transport layer 1114, and an electron-injection layer 1115 which are included in an EL layer 1102 are sequentially formed by a vacuum evaporation method.

After reducing the pressure in the vacuum evaporation apparatus to 10⁻⁴ Pa, 1,3,5-tri(dibenzothiophen-4-yl)benzene (abbreviation: DBT3P-II) and molybdenum(VI) oxide were co-evaporated with a mass ratio of DBT3P-II (abbreviation) to molybdenum oxide being 4:2, whereby the hole-injection layer 1111 was formed over the first electrode 1101. The thickness was 20 nm. Note that a co-evaporation method is an evaporation method in which a plurality of different substances is concurrently vaporized from respective different evaporation sources.

Then, 4-phenyl-4′-(9-phenylfluoren-9-yl)triphenylamine (abbreviation: BPAFLP) was evaporated to a thickness of 20 nm, so that the hole-transport layer 1112 was formed.

Next, the light-emitting layer 1113 was formed over the hole-transport layer 1112. For the light-emitting element 7, 4,6-bis[3-(4-dibenzothienyl)phenyl]pyrimidine (abbreviation: 4,6mDBTP2Pm-II) and N-(4-biphenyl)-N-(9,9′-spirobi-9H-fluoren-2-yl)-9-phenyl-9H-carbazol-3-amine (abbreviation: PCBiF) were co-evaporated with a mass ratio of 4,6mDBTP2Pm-II (abbreviation) to PCBiF (abbreviation) being 0.8:0.2, so that the light-emitting layer 1113 with a thickness of 40 nm was formed. For the light-emitting element 8, 4,6mDBTP2Pm-II (abbreviation) and N-(4-biphenyl)-N-(9,9-dimethyl-9H-fluoren-2-yl)-9-phenyl-9H-carbazol-3-amine (abbreviation: PCBiF) were co-evaporated with a mass ratio of 4,6mDBTP2Pm-II (abbreviation) to PCBiF (abbreviation) being 0.8:0.2, so that the light-emitting layer 1113 with a thickness of 40 nm was formed. For the light-emitting element 9, 4,6mDBTP2Pm-II (abbreviation) and N-(3-biphenyl)-N-(9,9-dimethyl-9H-fluoren-2-yl)-9-phenyl-9H-carbazol-3-amine (abbreviation: mPCBiF) were co-evaporated with a mass ratio of 4,6mDBTP2Pm-II (abbreviation) to mPCBiF (abbreviation) being 0.8:0.2, so that the light-emitting layer 1113 with a thickness of 40 nm was formed.

Then, 4,6mDBTP2Pm-II (abbreviation) was evaporated to a thickness of 10 nm over the light-emitting layer 1113 and bathophenanthroline (abbreviation: Bphen) was evaporated to a thickness of 15 nm, whereby the electron-transport layer 1114 having a stacked structure was formed. Furthermore, lithium fluoride was evaporated to a thickness of 1 nm over the electron-transport layer 1114, whereby the electron-injection layer 1115 was formed.

Finally, aluminum was evaporated to a thickness of 200 nm over the electron-injection layer 1115 to form a second electrode 1103 serving as a cathode; thus, the light-emitting element 7, the light-emitting element 8, and the light-emitting element 9 were obtained. Note that, in the above evaporation process, evaporation was all performed by a resistance heating method.

In the above-described manner, the light-emitting element 7, the light-emitting element 8, and the light-emitting element 9 were obtained. Table 7 shows element structures of the light-emitting element 7, the light-emitting element 8, and the light-emitting element 9.

TABLE 7

| | First | Hole-injection | Hole-transport | Light-emitting | Electron-transport | | Electron-injection | Second |
|---|---|---|---|---|---|---|---|---|
| | electrode | layer | layer | layer | layer | | layer | electrode |
| Light-emitting | ITSO | DBT3P-II:MoOx | BPAFLP | * | 4,6mDBTP2Pm-II | Bphen | LiF | Al |
| element 7 | (110 nm) | (4:2 20 nm) | (20 nm) | | (10 nm) | (15 nm) | (1 nm) | (200 nm) |
| Light-emitting | ITSO | DBT3P-II:MoOx | BPAFLP | ** | 4,6mDBTP2Pm-II | Bphen | LiF | Al |
| element 8 | (110 nm) | (4:2 20 nm) | (20 nm) | | (10 nm) | (15 nm) | (1 nm) | (200 nm) |
| Light-emitting | ITSO | DBT3P-II:MoOx | BPAFLP | *** | 4,6mDBTP2Pm-II | Bphen | LiF | Al |
| element 9 | (110 nm) | (4:2 20 nm) | (20 nm) | | (10 nm) | (15 nm) | (1 nm) | (200 nm) |

* 4,6mDBTP2Pm-II:PCBiF (0.8:0.2 40 nm)
** 4,6mDBTP2Pm-II:PCBiF (0.8:0.2 40 nm)
*** 4,6mDBTP2Pm-II:mPCBiF (0.8:0.2 40 nm)

Further, the fabricated light-emitting elements 7, 8, and 9 were sealed in a glove box containing a nitrogen atmosphere so as not to be exposed to the air (specifically, a sealant was applied onto outer edges of the elements and heat treatment was performed at 80° C. for 1 hour at the time of sealing).

### (Operation Characteristics of Light-Emitting Element 7, Light-Emitting Element 8, and Light-Emitting Element 9)

Operation characteristics of the fabricated light-emitting elements 7, 8, and 9 were measured. Note that the measurement was carried out at room temperature (in an atmosphere kept at 25° C.).

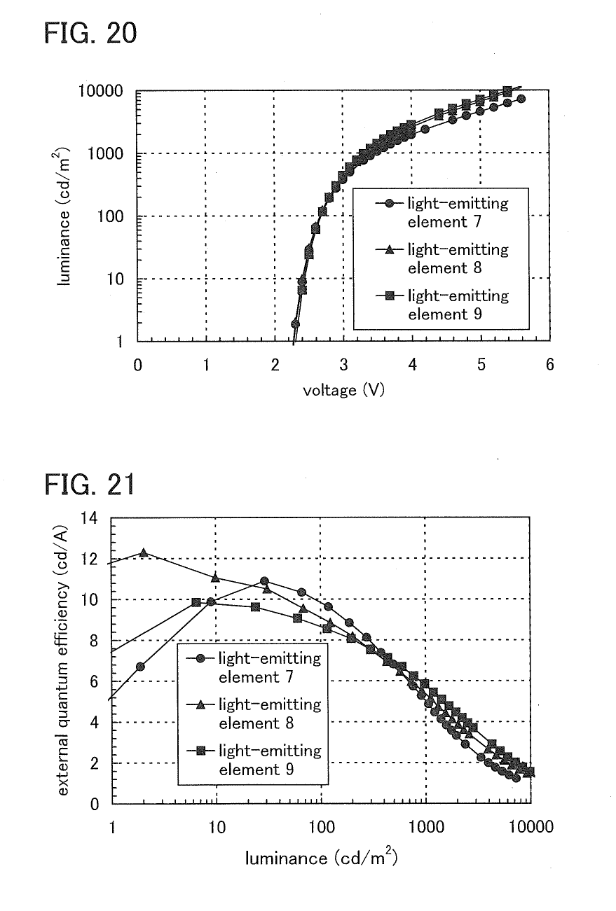

FIG. 20 and FIG. 21 show voltage-luminance characteristics and luminance-external quantum efficiency characteristics, respectively, of the light-emitting elements 7, 8, and 9.

According to FIG. 21, the light-emitting elements 7, 8, and 9, which are embodiments of the present invention, have maximum external quantum efficiencies of about 11%, about 12%, and about 9.9%, respectively. External quantum efficiencies exceeding the theoretical external quantum efficiency (5%) were obtained because the theoretical generation probability of S1 (25%) is increased by the formation of an exciplex in the light-emitting layer. Thus, the light-emitting element of one embodiment of the present invention is characterized by having a relatively high emission efficiency by contributing part of triplet excited energy to light emission, without the need of using a high-cost Ir complex as a light-emitting material.

Table 8 shows initial values of main characteristics of the light-emitting element 7, the light-emitting element 8, and the light-emitting element 9 at a luminance of about 1000 cd/m².

TABLE 8

| | | | | | | | | External |
|---|---|---|---|---|---|---|---|---|
| | | | Current | | | Current | Power | quantum |
| | Voltage | Current | density | Chromaticity | Luminance | efficiency | efficiency | efficiency |
| | (V) | (mA) | (mA/cm²) | (x, y) | (cd/m²) | (cd/A) | (lm/W) | (%) |
| Light-emitting | 3.5 | 0.26 | 6.4 | (0.37, 0.57) | 1100 | 17 | 15 | 4.9 |
| element 7 | | | | | | | | |
| Light-emitting | 3.3 | 0.19 | 4.8 | (0.37, 0.58) | 920 | 19 | 18 | 5.5 |
| element 8 | | | | | | | | |
| Light-emitting | 3.3 | 0.2 | 4.9 | (0.37, 0.58) | 980 | 20 | 19 | 5.8 |
| element 9 | | | | | | | | |

The results in Table 8 also show that the light-emitting element 7, the light-emitting element 8, and the light-emitting element 9 fabricated in this example have high luminance and high current efficiency.

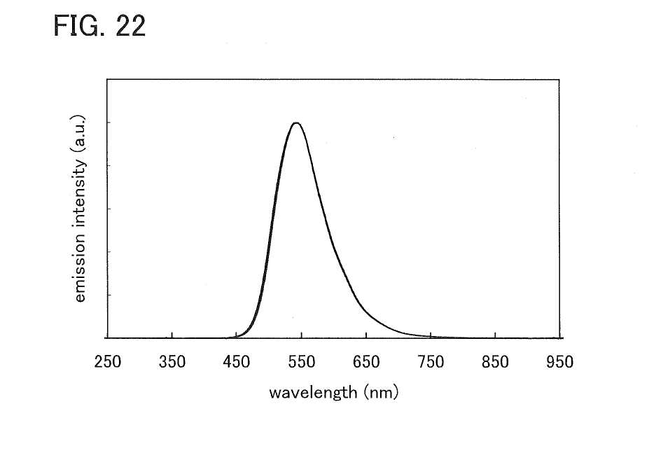

FIG. 22 shows emission spectra of the light-emitting element 7, the light-emitting element 8, and the light-emitting element 9 which were obtained by application of a current of 0.1 mA. As shown in FIG. 22, the light-emitting elements 7, 8, and 9 each have a peak of emission spectrum at around 550 nm; this peak derives from the emission of the exciplex formed in the light-emitting layer 1113.

Thus, the light-emitting element of one embodiment of the present invention in which the exciplex can be formed in the light-emitting layer was found to have high emission efficiency.

This application is based on Japanese Patent Application serial no. 2012-172824 filed with Japan Patent Office on Aug. 3, 2012, the entire contents of which are hereby incorporated by reference.

What is claimed is:

1. (canceled)

2. A light-emitting element comprising:
a pair of electrodes; and
a light-emitting layer between the pair of electrodes,
wherein the light-emitting layer comprises:
a first organic compound and a second organic compound that are capable of forming an exciplex; and
a compound capable of converting triplet excited energy into light emission,
wherein the first organic compound has an electron-transport property,
wherein the second organic compound has a p-phenylenediamine skeleton, and
wherein the compound comprises a thermally activated delayed fluorescence material.

3. The light-emitting element according to claim 2, wherein the light-emitting layer is configured so that an emission spectrum of the exciplex overlaps with an absorption spectrum of the compound capable of converting triplet excited energy into light emission.

4. The light-emitting element according to claim 2,
wherein a gap between S1 level and T1 level of the exciplex is smaller than a gap between S1 level and T1 level of the first organic compound, and
wherein the gap between S1 level and T1 level of the exciplex is smaller than a gap between S1 level and T1 level of the second organic compound.

5. The light-emitting element according to claim 2, wherein the first organic compound comprises a π-electron deficient heteroaromatic compound.

6. The light-emitting element according to claim 2, wherein the first organic compound comprises a nitrogen-containing heteroaromatic compound.

7. A light-emitting device comprising:
a pixel portion comprising:
a transistor; and
the light-emitting element according to claim 2,
wherein the light-emitting element is electrically connected to the transistor.

8. A light-emitting element comprising:
a pair of electrodes; and
a light-emitting layer between the pair of electrodes,
wherein the light-emitting layer comprises:
a first organic compound and a second organic compound that are capable of forming an exciplex; and
a compound capable of converting triplet excited energy into light emission,
wherein the first organic compound has an electron-transport property,
wherein the second organic compound has a 4-(9H-carbazol-9-yl)aniline skeleton, and
wherein the compound comprises a thermally activated delayed fluorescence material.

9. The light-emitting element according to claim 8, wherein the light-emitting layer is configured so that an emission spectrum of the exciplex overlaps with an absorption spectrum of the compound capable of converting triplet excited energy into light emission.

10. The light-emitting element according to claim 8,
wherein a gap between S1 level and T1 level of the exciplex is smaller than a gap between S1 level and T1 level of the first organic compound, and
wherein the gap between S1 level and T1 level of the exciplex is smaller than a gap between S1 level and T1 level of the second organic compound.

11. The light-emitting element according to claim 8, wherein the first organic compound comprises a n-electron deficient heteroaromatic compound.

12. The light-emitting element according to claim 8, wherein the first organic compound comprises a nitrogen-containing heteroaromatic compound.

13. A light-emitting device comprising:
a pixel portion comprising:
a transistor; and
the light-emitting element according to claim 8,
wherein the light-emitting element is electrically connected to the transistor.

14. A light-emitting element comprising:
a pair of electrodes; and
a light-emitting layer between the pair of electrodes,
wherein the light-emitting layer comprises:
a first organic compound and a second organic compound that are capable of forming an exciplex; and
a compound capable of converting triplet excited energy into light emission,
wherein the first organic compound has an electron-transport property,
wherein the second organic compound has a 9-aryl-9H-carbazol-3-amine skeleton, and
wherein the compound comprises a thermally activated delayed fluorescence material.

15. The light-emitting element according to claim 14, wherein the light-emitting layer is configured so that an emission spectrum of the exciplex overlaps with an absorption spectrum of the compound capable of converting triplet excited energy into light emission.

16. The light-emitting element according to claim 14,
wherein a gap between S1 level and T1 level of the exciplex is smaller than a gap between S1 level and T1 level of the first organic compound, and
wherein the gap between S1 level and T1 level of the exciplex is smaller than a gap between S1 level and T1 level of the second organic compound.

17. The light-emitting element according to claim 14, wherein the first organic compound comprises a n-electron deficient heteroaromatic compound.

18. The light-emitting element according to claim 14, wherein the first organic compound comprises a nitrogen-containing heteroaromatic compound.

19. The light-emitting element according to claim 14, wherein the second organic compound is represented by the following formula:

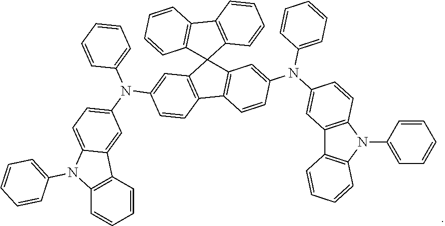 [SMILES: c1ccc(N(c2ccc3c(c2)C2(c4ccccc4-c4ccccc42)c2cc(N(c4ccccc4)c4ccc5c(c4)c4ccccc4n5-c4ccccc4)ccc2-3)c2ccc3c(c2)c2ccccc2n3-c2ccccc2)cc1]

20. A light-emitting device comprising:
a pixel portion comprising:
a transistor; and
the light-emitting element according to claim 14,
wherein the light-emitting element is electrically connected to the transistor.
